(19) United States
(12) Patent Application Publication
(10) Pub. No.: US 2025/0212535 A1
(43) Pub. Date: Jun. 26, 2025

(54) IMAGE SENSOR AND ELECTRONIC APPARATUS INCLUDING IMAGE SENSOR

(71) Applicant: SAMSUNG ELECTRONICS CO., LTD., Suwon-si (KR)

(72) Inventors: Junho Lee, Suwon-si (KR); Sookyoung Roh, Suwon-si (KR); Sungmo Ahn, Suwon-si (KR)

(73) Assignee: SAMSUNG ELECTRONICS CO., LTD., Suwon-si (KR)

(21) Appl. No.: 18/888,954

(22) Filed: Sep. 18, 2024

(30) Foreign Application Priority Data
Dec. 26, 2023 (KR) 10-2023-0191856

(51) Int. Cl. H01L 27/146; H01L 31/028; H01L 31/0368; H01L 31/105

(52) U.S. Cl. CPC H10F 39/182; H10F 30/223; H10F 39/802; H10F 39/805; H10F 77/122; H10F 77/1642

(57) ABSTRACT

An image sensor includes a plurality of pixels arranged two-dimensionally and each having a size less than or equal to a diffraction limit. Each of the plurality of pixels includes a sensing layer including two or more photodiodes, and a surrounding material filling an area around the first, second, and third photodiodes. The two or more photodiodes include first, second, and third photodiodes that selectively absorb lights in red, green, and blue wavelength bands, respectively. An anti-reflection layer (ARL) is located on a surface of the sensing layer. The ARL lowers reflectance of light incident on the sensing layer.

### CROSS-REFERENCE TO RELATED APPLICATION

This application is based on and claims priority under 35 U.S.C. § 119 to Korean Patent Application No. 10-2023-0191856, filed on Dec. 26, 2023, in the Korean Intellectual Property Office, the disclosure of which is incorporated by reference herein in its entirety.

### BACKGROUND

### 1. Field

Apparatuses and methods consistent with example embodiments relate to an image sensor and an electronic apparatus including the image sensor.

### 2. Description of the Related Art

Image sensors may detect the color of incident light by using a color filter. As the color filter absorbs light of colors other than the light of the corresponding color, the light use efficiency of the color filter may be lowered. For example, when an RGB color filter is used, ⅓ of the incident light is transmitted and the remaining ⅔ of the light is absorbed. As a result, the light use efficiency is merely around 33%. Most light loss in the image sensor occurs in the color filter. Accordingly, attempts have been made to separate colors by using each pixel of an image sensor without using a color filter.

As the demand for higher resolution increases, pixel sizes have been gradually reduced, which may limit a color separation function. In a color separation method, energy transmitted to a unit pixel is separately absorbed into R, G, and B effective areas, and thus, one color is handled per sub-pixel, and accordingly, resolution may deteriorate due to under-sampling, which is basically present in a signal processing process. Accordingly, research has been conducted on a method of implementing full color pixels suitable for high resolution implementation.

### SUMMARY

One or more embodiments provide an image sensor having a full color pixel and an electronic apparatus including the image sensor.

Further, one or more embodiments provide an image sensor with low surface reflectivity and an electronic apparatus including the image sensor.

According to an aspect of the present disclosure, an image sensor may include a plurality of pixels, wherein each of the plurality of pixels includes a sensing layer including a first photodiode configured to absorb light in a red wavelength band, a second photodiode configured to absorb light in a green wavelength band, a third photodiode configured to absorb light in a blue wavelength band, and a filling material provided around the first photodiode, the second photodiode, and the third photodiode; and an anti-reflection layer (ARL) provided on a light incident surface of the sensing layer to lower reflectance of light incident on the sensing layer. A refractive index of the ARL satisfies 1<n_{ARL}≤1.08×\sqrt{n_{S}×n_{AIR}}, when n_{ARL} denotes the refractive index of the ARL is n_{ARL}, n_{S} denotes a refractive index of the sensing layer is n_{S}, and n_{AIR} denotes a refractive index of air.

The ARL has a thickness in a range from 50 nm to 200 nm.

A ratio of a thickness of the ARL to a thickness of the sensing layer is in a range from 1/50 to 1/2.5.

The ARL has a single-layer structure.

The ARL has a flat surface.

The ARL including a coating layer covering the surface of the sensing layer and a plurality of hole patterns provided in the coating layer.

The ARL has a multi-layer structure.

The ARL may include a first layer covering the surface of the sensing layer and a second layer on the first layer.

The first layer may include a passivation layer.

The first layer and the second layer may include flat ARLs having different refractive indices.

The first layer may include a flat ARL, and a plurality of hole patterns may be provided in the second layer.

The ARL may include at least one of ALO, Al₂O₃, HfO, LTO, SiN, SiO₂, AlOC, AlON, MgF₂, and AlOCN.

Each of the first, the second, and the third photodiodes may include polysilicon, and the refractive index of the ARL may satisfy 1<n_{ARL}≤1.455.

Each of the first, the second, and the third photodiodes has a rod shape including a first conductive type semiconductor layer, an intrinsic semiconductor layer, and a second conductive type semiconductor layer, the first conductive type semiconductor layer, the intrinsic semiconductor layer, and the second conductive type semiconductor layer being stacked in one direction. Cross-sections of the first, the second, and the third photodiodes have a first width, a second width, and a third width, respectively, in a direction perpendicular to the one direction. The first width, the second width, and the third width may satisfy w1>w2>w3 when w1, w2, and w3 denote the first width, the second width, and the third width, respectively.

Each of the plurality of pixels may include four photodiodes consisting of the first photodiode, the second photodiode, the third photodiode, and an additional third photodiode. The first, the second, and the third photodiodes may be arranged in a square shape formed by a line connecting centers of the four photodiodes. The third photodiodes may be arranged in a diagonal direction of the square shape. The first width may be in a range from 110 nm to 140 nm, the second width is in a range from 80 nm to 115 nm, and the third width is in a range from 60 nm to 75 nm.

According to another aspect of the disclosure, an electronic apparatus may include: a lens assembly including one or more lenses and configured to form an optical image of a subject; the image sensor configured to convert the optical image into an electrical signal; and a processor configured to process the electrical signal generated by the image sensor.

According to another aspect of the disclosure, an image sensor may include a plurality of pixels, each of the plurality of pixels including: a sensing layer including: a plurality of photodiodes that extend in a vertical direction, that are spaced apart from each other in a horizontal direction, and that are configured to absorb light in a red wavelength band, in a green wavelength band, and in a blue wavelength band, respectively, and a filling material that fill gaps between the plurality of photodiodes; and an anti-reflection layer provided on a light incident surface of the sensing layer and configured to lower light reflectance on the image sensor, wherein the image sensor is configure to selectively absorb the light in the red wavelength band, in the green wavelength band, and in the blue wavelength band through the plurality of photodiodes without using a color filter.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic block diagram of an image sensor according to an embodiment;

FIG. 2 is a schematic cross-sectional view of a pixel of the image sensor shown in FIG. 1, according to an embodiment;

FIG. 3 is a plan view showing a pixel arrangement of a pixel array of the image sensor of FIG. 1;

FIG. 4 is a detailed perspective view showing an example of a structure of a pixel array of the image sensor of FIG. 1;

FIG. 5 is a plan view of FIG. 4;

FIGS. 6A and 6B are cross-sectional views taken along lines A-A and B-B of FIG. 5, respectively;

FIG. 7 is a schematic cross-sectional view showing an anti-reflection layer (ARL) according to an embodiment;

FIG. 8 is a schematic cross-sectional view showing an ARL according to an embodiment;

FIG. 9 is a schematic cross-sectional view showing an ARL according to an embodiment;

FIG. 10 is a graph showing an example of results of computational simulation on optical reflectance for normal incident light incident on a central area of an image sensor when an ARL is applied and when the ARL is not applied;

FIG. 11 is a graph showing an example of results of computational simulation on optical reflectance for cone incident light in the range of about 0 degree to about 8 degrees incident on a central area of an image sensor when an ARL is applied and when the ARL is not applied;

FIG. 12 shows results of computational simulation for color separation of blue, green, and red light in a central area of an image sensor when an ARL is not applied;

FIG. 13 shows the results of computational simulation for color separation of blue, green, and red light in a central area of an image sensor when an ARL with a refractive index of 1.48 is applied;

FIG. 14 shows the results of computational simulation for color separation of blue, green, and red light in a central area of an image sensor when an ARL with a refractive index of 1.39 is applied;

FIG. 15 is a graph showing an example of results of computational simulation for optical reflectance for normal incident light incident on an outer area of an image sensor when an ARL is applied and when the ARL is not applied;

FIG. 16 shows the results of computational simulation for color separation of blue, green, and red light in an outer area of an image sensor when an ARL is not applied;

FIG. 17 shows the results of computational simulation for color separation of blue, green, and red light in an outer area of an image sensor when an ARL with a refractive index of 1.39 is applied;

FIG. 18 is a graph showing the results of computational simulation for determining a range of a refractive index of an ARL;

FIG. 19A shows the results of computational simulation for reflectance and color separation performance when changing a size of a first photodiode;

FIG. 19B shows the results of computational simulation for reflectance and color separation performance when changing a size of a second photodiode;

FIG. 19C shows the results of computational simulation for reflectance and color separation performance when changing a size d_{B} of a third photodiode;

FIGS. 20 to 22 are plan views showing an arrangement of various types of photodiodes provided in one pixel in each image sensor according to other embodiments;

FIG. 23 is a block diagram illustrating an example of an electronic apparatus including an image sensor according to embodiments;

FIG. 24 is a schematic block diagram illustrating a camera module of FIG. 23; and

FIGS. 25 to 34 are diagrams showing various examples of an electronic apparatus including image sensors according to embodiments.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

As used herein, the term “and/or” includes any and all combinations of one or more of the associated listed items. Expressions such as “at least one of,” when preceding a list of elements, modify the entire list of elements and do not modify the individual elements of the list.

Hereinafter, the term “above” or “on” may include not only being directly above in contact but also being above without contact.

The terms such as “first” and “second” are used herein merely to describe a variety of constituent elements, but are used simply for the purpose of distinguishing one constituent element from another constituent element. These terms do not limit a difference in material or structure of the constituent elements.

The singular expressions include the plural expressions unless clearly specified otherwise in context. When a certain component “includes” a certain component, this indicates that the component may further include another component instead of excluding another component unless there is no different disclosure.

The terms, such as “unit” or “module” need to be understood as a unit that processes at least one function or operation and that may be embodied in a hardware manner, a software manner, or a combination of the hardware manner and the software manner.

The use of term “the” and similar referents are to be construed to cover both the singular and the plural.

Operations constituting a method may be performed in any suitable order unless explicitly stated that the operations need to be performed in the order described. The use of all exemplary terms (e.g., and for example) is simply for explaining the technical spirit in detail, and unless limited by the claims, the scope of the claims is not limited by these terms.

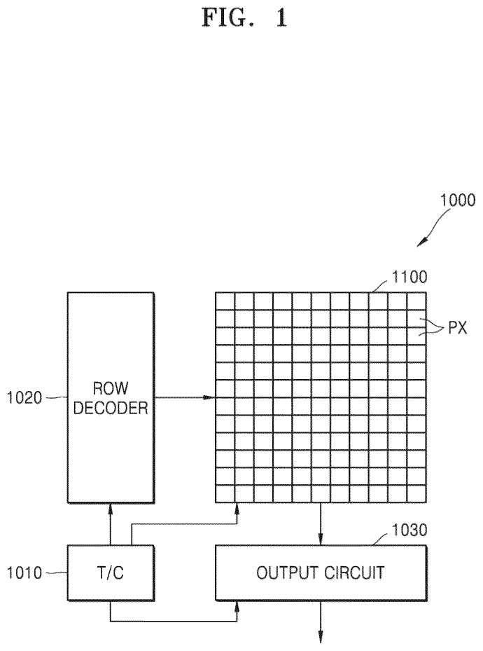

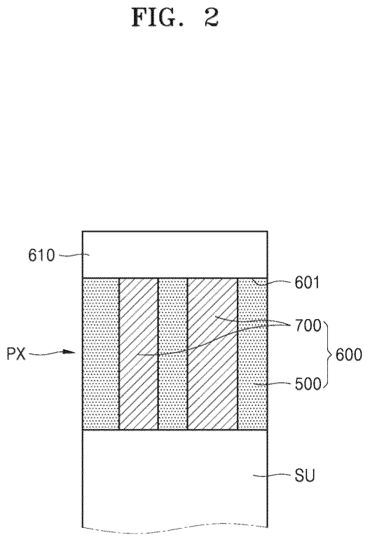

FIG. 1 is a schematic block diagram of an image sensor 1000 according to an embodiment. FIG. 2 is a schematic cross-sectional view of a pixel PX of the image sensor 1000 shown in FIG. 1, according to an embodiment. Referring to FIGS. 1 and 2, the image sensor 1000 includes a plurality of pixels PX arranged two-dimensionally. Each of the plurality of pixels PX has a size less than or equal to a diffraction limit. Each of the plurality of pixels PX includes a sensing layer 600. The sensing layer 600 includes two or more photodiodes 700, which selectively absorb light in two or more different wavelength bands, and a surrounding material 500 that fills an area around the two or more photodiodes 700. The surrounding material 500 may include SiO₂, Si₃N₄, Al₂O₃, and/or air. The surrounding material 500 may be also referred to as a filling material since the surrounding material 500 fills the gaps between the photodiodes 700. An anti-reflection layer (ARL) 610 that lowers reflectance of light incident on the sensing layer 600 is provided on a surface (e.g., a top surface) 601 of the sensing layer 600, while a circuit board SU is provided on an opposite surface (e.g., a bottom surface) of the sensing layer 600. The surface 601 may be referred to as a light incident surface.

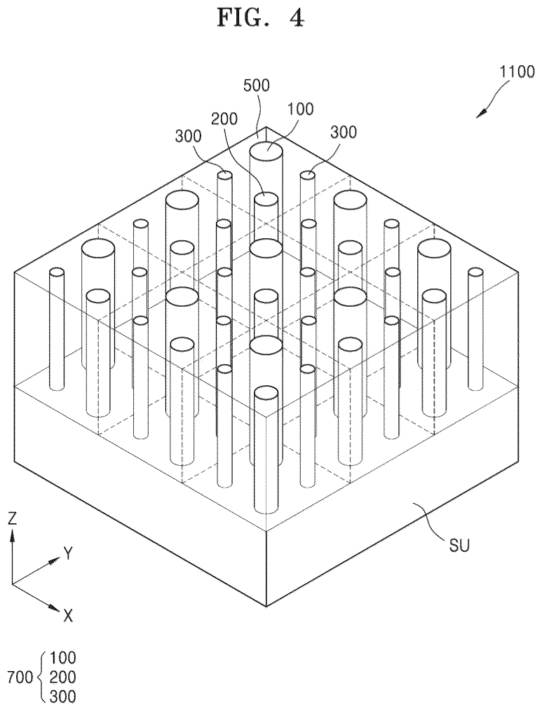

Referring to FIG. 1, the image sensor 1000 may include a pixel array 1100, a timing controller 1010, a row decoder 1020, and an output circuit 1030. The pixel array 1100 includes the plurality of pixels PX arranged two-dimensionally along a plurality of rows and columns. Each of the pixels PX may include a plurality of P-I-N photodiodes. This will be explained in detail below with reference to FIG. 4.

The row decoder 1020 selects one row of the pixel array 1100 in response to a row address signal output from the timing controller 1010. The output circuit 1030 outputs a light detection signal in column units from a plurality of pixels arranged along the selected row. To this end, the output circuit 1030 may include a column decoder and an analog to digital converter (ADC). For example, the output circuit 1030 may include a plurality of ADCs arranged for each column between the column decoder and the pixel array 1100, or one ADC arranged at an output terminal of the column decoder. The timing controller 1010, the row decoder 1020, and the output circuit 1030 may be implemented as one chip or as separate chips. A processor for processing an image signal output through the output circuit 1030 may be integrated into a single chip along with the timing controller 1010, the row decoder 1020, and the output circuit 1030.

Each of the plurality of pixels PX constituting the pixel array 1100 may selectively absorb light in two or more different wavelength bands. For example, each of the plurality of pixels PX constituting the pixel array 1100 may be a full-color pixel for detecting any color. That is, the light incident on the pixel PX may be divided for each wavelength band, and for example, the amounts of a red light component, a green light component, and a blue light component may be detected separately. Accordingly, a loss of light of a specific color depending on color of a sub-pixel, which occurs in an existing image sensor with a color filter, may not occur in the image sensor according to the present embodiment. In other words, each color component of the light incident on the pixel PX may be detected almost regardless of a region position within the pixel PX. In this regard, the pixel PX of the image sensor 1000 according to the embodiment may be referred to as a full-color pixel, or may be referred to as an RGB pixel as distinguished from a red pixel, a green pixel, or a blue pixel that recognizes a certain color alone.

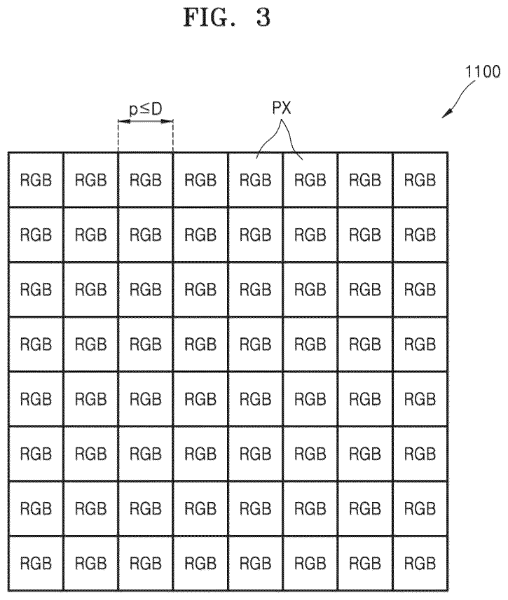

FIG. 3 is a plan view showing a pixel arrangement of the pixel array 1100 of the image sensor 1000 of FIG. 1. Referring to FIG. 3, the pixels PX may be arranged two-dimensionally. A width p of the pixel PX has a size less than or equal to a diffraction limit D. Here, the width refers to a width in one direction defining a two-dimensional array, and widths in both directions may be less than or equal to the diffraction limit D. The diffraction limit D refers to a minimum size at which an object is to be separated and imaged, and may be expressed according to the following equation.

D=λ/(2NA)=λ*F

Here, λ means a wavelength, and NA and F mean a numerical aperture and an F number of an imaging optical system, respectively.

NA is defined as a sine value of an edge ray angle in an imaging space, and as NA is increases, an angular distribution of focused light increases. The F number is defined as a relationship of 1/(2NA). As imaging systems are gaining higher resolution and becoming miniaturized, the edge ray angle tends to increase, and accordingly, module lenses with a small F number have been developed. When the F number ideally decreases to about 1.0, the diffraction limit is represented by X.

Under this assumption, the diffraction limit may be expressed as 0.45 μm based on a center wavelength of blue light. That is, each pixel PX constituting the pixel array 1100 may have a size of 0.45 μm×0.45 μm or less. However, these numbers are illustrative, and the detailed size may be changed depending on the imaging optical system provided. The minimum width of the pixel PX may be set depending on the size and number of the photodiodes 700 provided in the pixel PX. The width of the pixel PX may be, for example, 0.25 μm or more, or 0.3 μm or more, but is not limited thereto.

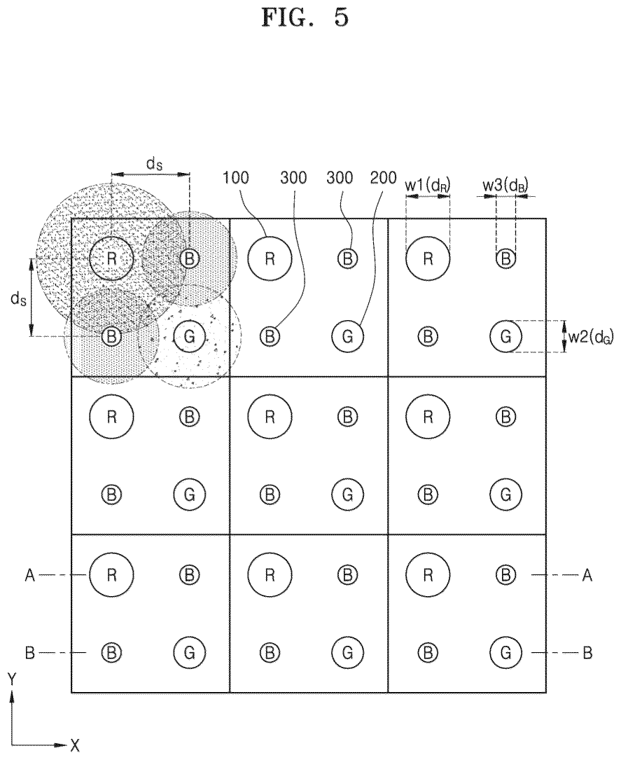

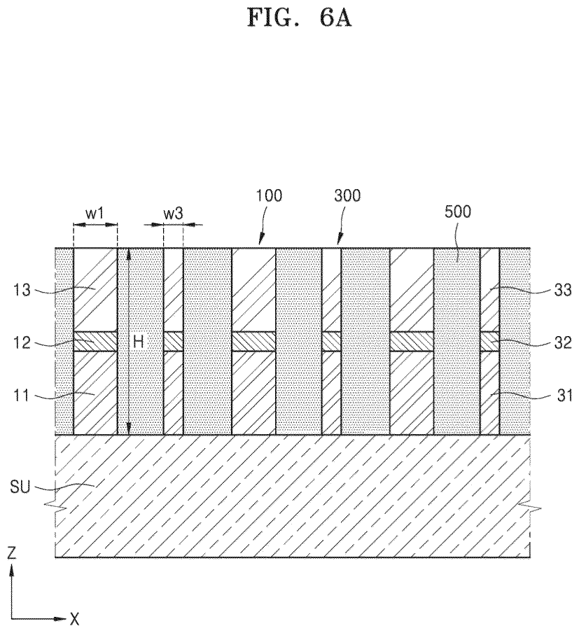

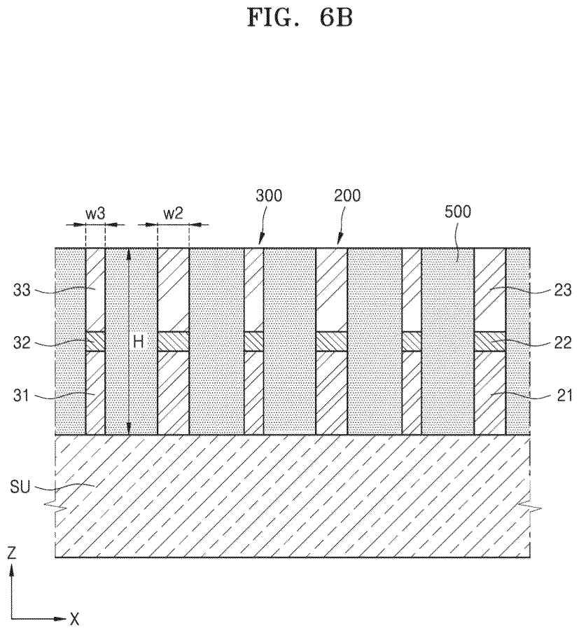

FIG. 4 is a detailed perspective view showing an example of a structure of the pixel array 1100 of the image sensor 1000 of FIG. 1. FIG. 5 is a plan view of FIG. 4, and FIGS. 6A and 6B are cross-sectional views taken along lines A-A and B-B of FIG. 5, respectively.

As shown in FIG. 2, each of the plurality of pixels PX constituting the pixel array 1100 includes the sensing layer 600. An existing pixel includes, for example, a color filter that decomposes visible light into red, green, and blue light, a plurality of photodiodes that selectively absorb red, green, and blue light, and a micro lens for incident red, green, and blue light onto the corresponding photodiode. The sensing layer 600 according to embodiments of the disclosure has a structure that integrates roles of the existing color filter, photo diode, and micro lens. To this end, the sensing layer 600 includes the two or more photodiodes 700 that selectively absorb light in two or more different wavelength bands, and the surrounding material 500 that fills an area around the two or more photodiodes 700. For example, as shown in FIG. 4, the sensing layer 600 of each of the plurality of pixels PX may include a first photodiode 100 that selectively absorbs light in a red wavelength band, a second photodiode 200 that selectively absorbs a green wavelength band, and a third photodiode 300 that selectively absorbs light in a blue wavelength band. In one embodiment, the color filter and the micro lens positioned in front of the sensing layer 600 may be omitted, as the sensing layer 600 assumes the functions of the existing color filter and micro lens.

The first photodiode 100, the second photodiode 200, and the third photodiode 300 are rod-shaped vertical photodiodes that extends in a vertical direction (z-direction). Each photodiode 100, 200, and 30 may have a shape dimension (e.g., a width of a cross-section area of each photodiode) smaller than a wavelength of incident light, and selectively absorb light in a certain wavelength band by waveguide mode-based resonance. The first photodiode 100, the second photodiode 200, and the third photodiode 300 have different cross-sectional widths w1, w2, and w3, respectively, perpendicular to a longitudinal direction Z. The widths w1, w2, and w3 may range from about 50 nm to about 200 nm, for example. The widths w1, w2, and w3 are set to guide light of a wavelength that satisfies each waveguide mode resonance requirement from among lights incident on the pixel PX inside the corresponding photodiode. For example, w1 may be about 120 nm and may range from about 110 nm to about 140 nm. w2 may be about 90 nm and may range from about 80 nm to about 115 nm. w3 may be about 70 nm and may range from about 60 nm to about 75 nm. Red light, green light, and blue light from among incident lights may be absorbed by the first photodiode 100, the second photodiode 200, and the third photodiode 300, which have the above widths, respectively. As shown in FIG. 5, circles indicated around the first, second, and third photodiodes 100, 200, and 300 conceptually illustrate guiding of red, green, and blue lights into the first, second, and third photodiodes 100, 200, and 300, respectively, but the disclosure is not limited thereto. Most of red light incident on any position within an area of the pixel PX may be absorbed by the first photodiode 100, most of green light may be absorbed by the second photodiode 200, and most of blue light may be absorbed by the third photodiode 300.

According to an embodiment, one pixel PX may include one first photodiode 100 that absorbs red light, one second photodiode 200 that absorbs green light, and two third photodiodes 300 that absorb blue light. The first, second, and third photodiodes 100, 200, and 300 may be arranged in a square shape obtained by lines connecting centers of the four photodiodes, and two third photodiodes 300 may be arranged in a diagonal direction of the square shape. However, this arrangement is illustrative.

A height H of each of the first photodiode 100, the second photodiode 200, and the third photodiode 300 may be about 500 nm or more, 1 μm or more, or 2 μm or more. According to an embodiment, the height H of each of the first photodiode 100, the second photodiode 200, and the third photodiode 300 may be about 500 nm to about 2500 nm. This height may be set in consideration of a position at which light incident into the photodiode is absorbed, that is, a position from an upper surface of the photodiode. Shorter wavelength light with higher energy is absorbed closer to the upper surface of the photodiode, and longer wavelength light is absorbed further away from the upper surface of the photodiode. The first photodiode 100, the second photodiode 200, and the third photodiode 300 may have the same height as shown in the drawings. When all photodiodes have the same height, a manufacturing process may generally become simpler. In this case, a height can be determined based on achieving sufficient light absorption in a long wavelength band. However, the disclosure is not limited thereto, and the first photodiode 100, the second photodiode 200, and the third photodiode 300 may be set to have different heights. For example, the height h1 of the first photodiode 100, the height h2 of the second photodiode, and the height h3 of the third photodiode may satisfy h1>h2>h3. An appropriate upper limit may be set for these heights in consideration of quantum efficiency and process difficulty for each wavelength, and may be, for example, 10 μm or less, or 5 μm or less.

The first, second, and third photodiodes 100, 200, and 300 are rod-shaped P-I-N photodiodes. The first photodiode 100 may include a first conductive type semiconductor layer 11, an intrinsic semiconductor layer 12, and a second conductive type semiconductor layer 13. The second photodiode 200 may include a first conductive type semiconductor layer 21, an intrinsic semiconductor layer 22, and a second conductive type semiconductor layer 23, and the third photodiode 300 may include a first conductive type semiconductor layer 31, an intrinsic semiconductor layer 32, and a second conductive type semiconductor layer 33. The first, second, and third photodiodes 100, 200, and 300 are shown in a cylindrical shape, but are not limited thereto. For example, a polygonal pillar shape such as a square pillar or a hexagonal pillar may be adopted.

The first, second, and third photodiodes 100, 200, and 300 may be formed based on a silicon semiconductor. For example, the first conductive type semiconductor layers 11, 21, and 31 may be p-type Si (p-Si), the intrinsic semiconductor layers 12, 22, and 32 may be intrinsic Si (i-Si), and the second conductive type semiconductor layers 13, 23, and 33 may be n-type Si (n-Si). The first conductive type semiconductor layers 11, 21, and 31 may be n-Si, and the second conductive type semiconductor layers 13, 23, and 33 may be p-Si.

The surrounding material 500 of the first, second, and third photodiodes 100, 200, and 300 may be air, or may be a material having a lower refractive index than refractive indices of the first, second, and third photodiodes 100, 200, and 300. For example, SiO₂, Si₃N₄, or Al₂O₃ may be used as a surrounding material.

A circuit board SU may support a plurality of first, second, and third photodiodes 100, 200, and 300, and may include circuit elements that process signals from each pixel PX. For example, electrodes and wiring structures for the first, second, and third photodiodes 100, 200, and 300 provided in the pixel PX may be provided on the circuit board SU. Various circuit elements required for the image sensor 1000 may be integrated and arranged on the circuit board SU. For example, a logic layer including various analog circuits and digital circuits may be provided, and a memory layer in which data is stored may be provided. The logic layer and the memory layer may be formed as different layers or the same layer. Some of the circuit elements illustrated in FIG. 1 may be provided on the circuit board SU.

In an embodiment, the image sensor 1000 may lack a color filter installed in front of the sensing layer 600 of the pixel PX. Accordingly, light passes through the surface 601 of the sensing layer 600 directly from an external medium, for example, air, before reaching the sensing layer 600. When light travels from one medium to another medium, an increase in the refractive index contrast between the two different media leads to higher reflectance at a boundary surface between the two media. A refractive index of the sensing layer 600 may be calculated by applying fill factors of a photodiode 700 and the surrounding material 500 to refractive indices of the photodiode 700 and the surrounding material 500, respectively. The fill factors of the photodiode 700 and the surrounding material 500 may be volume fractions of the photodiode 700 and the surrounding material 500 with respect to the entire volume of the sensing layer 600. A refractive index of the surrounding material forming the sensing layer 600, for example, a refractive index in a visible light range of SiO₂ is about 1.5. In contrast, a refractive index of silicon forming the photodiode 700, for example, a refractive index in a visible light range of poly-silicon (poly-Si) is about 4, which is very high compared to air. Therefore, the refractive index of the sensing layer 600 is significantly higher than a refractive index of air. Therefore, when light is incident directly from air to the sensing layer 600, the amount of light reflected from the surface 601 of the sensing layer 600 may increase, thereby reducing light use efficiency. Due to a high refractive index difference between air and the sensing layer 600, artifacts such as flares and ghosts may occur during photography.

According to embodiments of the disclosure, the ARL 610 may be located at a light incident side of the sensing layer 600 to lower the reflectance of light incident on the sensing layer 600. For example, the ARL 610 may be located on the surface 601 of the sensing layer 600. The ARL 610 may cover the surface 601 of the sensing layer 600. The refractive index of the ARL 610 may have a value between a refractive index of the external medium, for example, air, and a refractive index of the sensing layer 600. The ARL 610 may include, for example, at least one of ALO, Al₂O₃, AlOC, AlON, AlOCN, HfO, LTO, MgF₂, SiN, and SiO₂, but is not limited thereto. Various high refractive index transparent polymer materials may be used as the ARL 610. In the embodiment shown in FIG. 2, the ARL 610 has a single-layer structure with one material layer and entirely covers the surface 601 of the sensing layer 600. This type of ARL may be referred to as a flat anti-reflection layer.

According to this configuration, the light reflectance on the surface 601 of the sensing layer 600 may be reduced, and the light use efficiency of the image sensor 1000 may be improved. Degradation of captured image quality due to artifacts such as flares and ghosts may be reduced or prevented by reducing a difference in refractive index between the external medium and the sensing layer 600. In addition, the ARL 610 is directly located on the sensing layer 600 without a color filter intervening, and thus the structure of the image sensor 1000 may be simplified and the manufacturing process cost of the image sensor 1000 may be reduced.

The refractive index of the ARL 610 may affect the color separation performance of the photodiodes 700 included in the sensing layer 600. The refractive index of the ARL 610 may be determined to lower the light reflectance on the surface 601 of the sensing layer 600 and to have a small effect on the color separation performance of the sensing layer 600. When a refractive index of the sensing layer 600 is n_{S} and a refractive index of air is n_{AIR}, the refractive index n_{ARL} of the ARL may satisfy Inequation (1) below.

$$1 < {n}_{A R L} \leq 1.08 \times \sqrt{{n}_{s} \times {n}_{AIR}} \qquad Inequation ( 1 )$$

The height H of each of the first photodiode 100, the second photodiode 200, and the third photodiode 300 corresponds to the thickness of the sensing layer 600, and may be in a range from about 500 nm to about 2500 nm. The thickness of the ARL 610 may be 50 nm or more in consideration of functionality as an ARL. When a thickness of the ARL 610 exceeds 200 nm, it may be difficult to ensure low reflectivity, for example, 2% or less in a long wavelength range, for example, a red area. Considering this, a ratio of a thickness of the ARL 610 to a thickness of the sensing layer 600 may be about 1/50 to about 1/2.5. The thickness of the ARL 610 may be about 50 nm to about 200 nm.

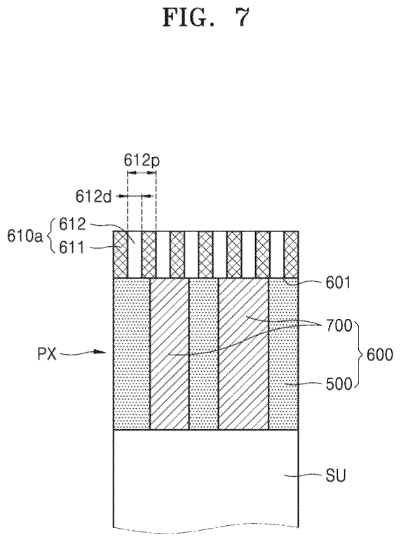

FIG. 7 is a schematic cross-sectional view showing an ARL 610a according to an embodiment. Referring to FIG. 7, the ARL 610a is formed on the surface 601 of the sensing layer 600. The ARL 610a includes a coating layer 611 that covers the surface 601 of the sensing layer 600, and a plurality of pattern holes 612 provided in the coating layer 611. The plurality of pattern holes 612 may be formed to pass through the coating layer 611. In some cases, the plurality of pattern holes 612 may be formed concavely from an upper surface of the coating layer 611 toward a lower surface without penetrating the coating layer 611. The plurality of pattern holes 612 may be arranged two-dimensionally. The plurality of pattern holes 612 may be distributed regularly or irregularly. The plurality of pattern holes 612 may have various shapes, such as circular, oval, polygonal, or irregular shapes. The coating layer 611 may include, for example, at least one of ALO, Al₂O₃, AlOC, AlON, AlOCN, HfO, LTO, MgF₂, SiN, and SiO₂, but is not limited thereto. Various high refractive index transparent polymer materials may be used as the coating layer 611. The inside of the plurality of pattern holes 612 may be filled with a material that has a different refractive index than the coating layer 611, for example, a material with a lower refractive index than the coating layer 611. For example, the inside of the plurality of pattern holes 612 may be filled with air. In this case, the pattern hole 612 may be referred to as an air hole. The plurality of pattern holes 612 may have nano-level sizes. Accordingly, the plurality of pattern holes 612 may also be referred to as nano-pattern holes.

The volume fraction of the plurality of pattern holes 612 varies depending on a shape, a size 612d, a pitch 612p, and a number of the plurality of pattern holes 612. The refractive index of the ARL 610a may vary depending on the volume fraction of the plurality of pattern holes 612 within the ARL 610a. The volume fraction of the plurality of pattern holes 612 may be determined such that the refractive index of the ARL 610a satisfies the inequation (1) described above.

According to this configuration, the refractive index of the ARL 610a may be changed using the plurality of pattern holes 612. In other words, the shape, the size 612d, the pitch 612p, and the number of the plurality of pattern holes 612 may be changed such that the refractive index of the ARL 610a satisfies the inequation (1) described above. Therefore, the refractive index of the ARL 610a may be precisely adjusted without changing a material of the coating layer 611. A range of selection of materials forming the ARL 610a may be widened, and a high degree of freedom in material selection may be ensured in a manufacturing process of the image sensor 1000.

The above description of the ratio of the thickness of the ARL 610 to the thickness of the sensing layer 600 and the thickness range of the ARL 610 is equally applied to a ratio of the thickness of the ARL 610a to the thickness of the sensing layer 600 and a thickness range of the ARL 610a. Accordingly, the ratio of the thickness of the ARL 610a to the thickness of the sensing layer 600 may be about 1/50 to about 1/2.5, and the thickness of the ARL 610a may be about 50 nm to about 200 nm.

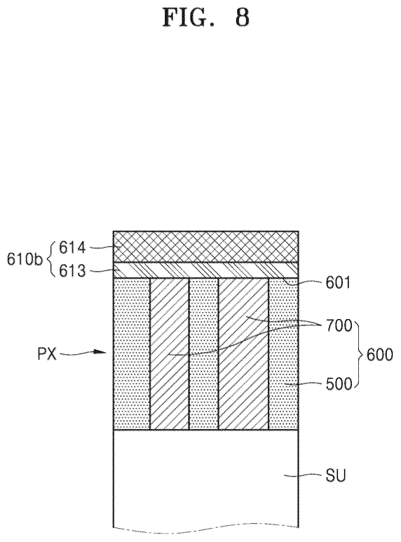

In the embodiments shown in FIGS. 2 and 7, the ARLs 610 and 610a have a single-layer structure with one material layer. A layer structure of the ARL is not limited thereto. For example, the ARL may have a multilayer structure having two or more material layers stacked. FIG. 8 is a schematic cross-sectional view showing an ARL 610b according to an embodiment. Referring to FIG. 8, the ARL 610b may include a first layer 613 formed on the surface 601 of the sensing layer 600, and a second layer 614 formed on the first layer 613. The first layer 613 entirely covers the surface 601 of the sensing layer 600, and the second layer 614 entirely covers the first layer 613. Accordingly, the first layer 613 and the second layer 614 are flat anti-reflection layers. The first layer 613 and the second layer 614 may include, for example, at least one of ALO, Al₂O₃, AlOC, AlON, AlOCN, HfO, LTO, MgF₂, SiN, and SiO₂, but is not limited thereto. Various high refractive index transparent polymer materials may be used as the first layer 613 and the second layer 614. A material forming the first layer 613 and the second layer 614 may be selected such that an effective refractive index of the ARL 610b including the first layer 613 and the second layer 614 satisfies the inequation (1) described above. The effective refractive index of the ARL 610b may be determined by a product of a refractive index of each of the first layer 613 and the second layer 614 and a ratio of thicknesses thereof.

According to this configuration, the ARL 610b that has a refractive index satisfying inequation (1) may be easily implemented by changing at least one of a material combination and a thickness combination of a plurality of layers, for example, the first layer 613 and the second layer 614. The refractive index of the ARL 610b may be precisely adjusted by changing the thickness combination when the material combination is determined. Accordingly, a range of selection of materials forming the ARL 610b may be widened, and a high degree of freedom in material selection may be ensured in a manufacturing process of the image sensor 1000.

The first layer 613 of the ARL 610b may operate as a passivation layer that protects the sensing layer 600 during a manufacturing process of the image sensor 1000. Accordingly, the first layer 613 may include a material suitable for a passivation layer. The above description of the ratio of the thickness of the ARL 610 to the thickness of the sensing layer 600 and the thickness range of the ARL 610 is equally applied to a ratio of the thickness of the ARL 610b to the thickness of the sensing layer 600 and a thickness range of the ARL 610b. Accordingly, the ratio of the thickness of the ARL 610b to the thickness of the sensing layer 600 may be about 1/50 to about 1/2.5, and the thickness of the ARL 610b may be about 50 nm to about 200 nm. The thickness of the ARL 610b is the sum of the thicknesses of the first layer 613 and the second layer 614.

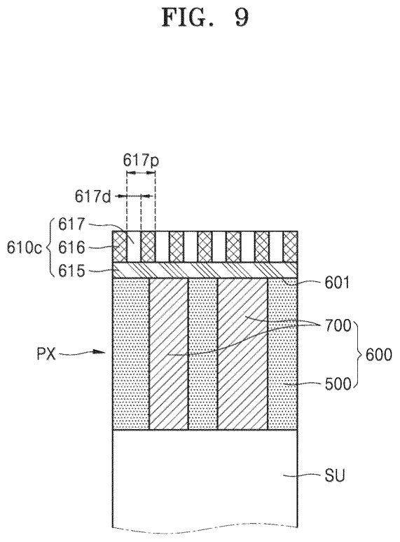

FIG. 9 is a schematic cross-sectional view showing an ARL 610c according to an embodiment. Referring to FIG. 9, the ARL 610c may include a first layer 615 formed on the surface 601 of the sensing layer 600, and a second layer 616 that is formed on the first layer 615 and in which a plurality of pattern holes 617 are formed. The first layer 615 is a flat anti-reflection layer that entirely covers the surface 601 of the sensing layer 600. The plurality of pattern holes 617 may be formed to pass through the second layer 616. In some cases, the plurality of pattern holes 617 may be formed concavely from an upper surface of the second layer 616 toward a lower surface, without penetrating the second layer 616. The plurality of pattern holes 617 may be arranged two-dimensionally. The plurality of pattern holes 617 may be distributed regularly or irregularly. The plurality of pattern holes 617 may have various shapes, such as circular, oval, polygonal, or irregular shapes. The first layer 615 and the second layer 616 may include, for example, at least one of ALO, Al₂O₃, AlOC, AlON, AlOCN, HfO, LTO, MgF₂, SiN, and SiO₂, but is not limited thereto. Various high refractive index transparent polymer materials may be used as the first layer 615 and the second layer 616. The inside of the plurality of pattern holes 617 may be filled with a material that has a different refractive index than the second layer 616, for example, a material with a lower refractive index than the second layer 616. For example, the inside of the plurality of pattern holes 617 may be filled with air. In this case, the pattern hole 617 may be referred to as an air hole. The plurality of pattern holes 617 may have nano-level sizes. Accordingly, the plurality of pattern holes 617 may also be referred to as nano-pattern holes.

The volume fraction of the plurality of pattern holes 617 in the second layer 616 varies depending on a shape, a size 617d, a pitch 617p, and a number of the plurality of pattern holes 617. The refractive index of the second layer 616 may vary depending on the volume fraction of the plurality of pattern holes 612. The effective refractive index of the ARL 610c may be determined by a product of a refractive index of each of the first layer 615 and the second layer 616 and a ratio of thicknesses thereof. The volume fraction of the plurality of pattern holes 617, a material combination and a thickness combination of the first layer 615 and the second layer 616 may be determined such that the refractive index of the ARL 610c satisfies the inequation (1) described above.

According to this configuration, the refractive index of the ARL 610c may be precisely adjusted to satisfy the inequation (1) described above using the material combination and thickness combination of the first layer 615 and the second layer 616 as well as the plurality of pattern holes 617. Accordingly, a range of selection of materials forming the ARL 610c may be widened, and a high degree of freedom in material selection may be ensured in a manufacturing process of the image sensor 1000.

The first layer 615 of the ARL 610c may operate as a passivation layer that protects the sensing layer 600 during a manufacturing process of the image sensor 1000. Accordingly, the first layer 615 may include a material suitable for a passivation layer. The above description of the ratio of the thickness of the ARL 610 to the thickness of the sensing layer 600 and the thickness range of the ARL 610 is equally applied to a ratio of the thickness of the ARL 610c to the thickness of the sensing layer 600 and a thickness range of the ARL 610c. Accordingly, the ratio of the thickness of the ARL 610c to the thickness of the sensing layer 600 may be about 1/50 to about 1/2.5, and the thickness of the ARL 610c may be about 50 nm to about 200 nm. The thickness of the ARL 610c is the sum of the thicknesses of the first layer 615 and the second layer 616.

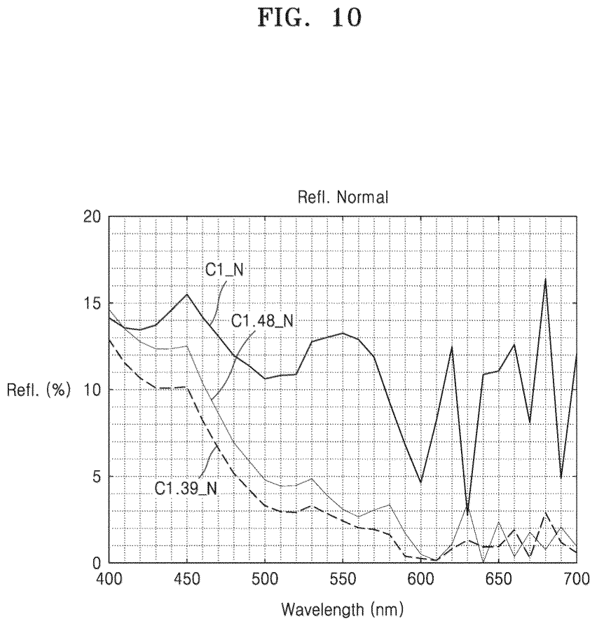

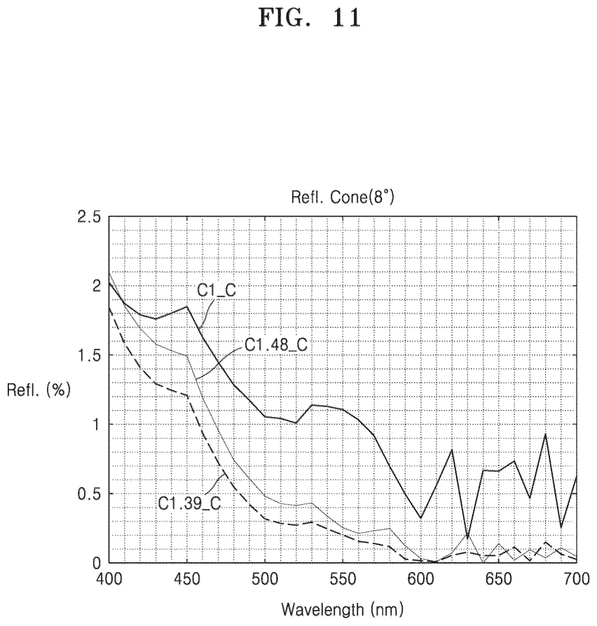

The application of an ARL may lead to improvement in optical reflectance, which may be checked via computational simulation for optical reflectance in a central area of the image sensor 1000, that is, an area with a chief ray angle (CRA)=0. FIG. 10 is a graph showing an example of results of computational simulation on optical reflectance for normal incident light incident on a central area of the image sensor 1000 when an ARL is applied and when the ARL is not applied. FIG. 11 is a graph showing an example of results of computational simulation on optical reflectance for cone incident light in the range of about 0 degree to about 8 degrees incident on a central area of the image sensor 1000 when an ARL is applied and when the ARL is not applied. Normal incident light represents light that is perpendicularly incident on the sensing layer 600.

Conditions for computational simulation are explained. As shown in FIG. 5, in the pixel PX, the first photodiode 100, the second photodiode 200, and the two third photodiodes 300 are arranged at vertices of a square. The first photodiode 100 and the second photodiode 200 face each other in a diagonal direction, and the two third photodiodes 300 face each other in another diagonal direction. d_{R}, d_{G}, d_{B}, and d_{S} are 120 nm, 90 nm, 70 nm, and 150 nm, respectively. The first photodiode 100, the second photodiode 200, and the third photodiode 300 include polysilicon. The surrounding material 500 includes SiO₂. The refractive index n_{S} of the sensing layer 600, considering the volume fraction of the first photodiode 100, the second photodiode 200, and the third photodiode 300 and the volume fraction of the surrounding material 500, is about 1.9. In this case, the refractive index of an ideal ARL is \sqrt{n_{S}×n_{AIR}} ≈1.38. The computational simulation is performed with the refractive index of the ARL being 1.39 and 1.48, and the results are shown in FIGS. 10 and 11. In FIG. 10, C1_N represents optical reflectance for normal incident light when an ARL is not applied, C1.39_N represents optical reflectance for normal incident light when an ARL with a refractive index of 1.39 is applied, and C1.48_N represents optical reflectance for normal incident light when an ARL with a refractive index of 1.48 is applied. In FIG. 11, C1_C represents optical reflectance for cone incident light in the range of about 0 degree to about 8 degrees when an ARL is not applied, C1.39_C represents optical reflectance for cone incident light when an ARL with a refractive index of 1.39 is applied, and C1.48_C represents optical reflectance for cone incident light when an ARL with a refractive index of 1.48 is applied. Average reflectance may be summarized as Table 1.

TABLE 1

| | Average reflectance (%) | | |
|---|---|---|---|
| | | Refractive index of | Refractive index of |
| | ARL is | reflective layer | reflective layer |
| | not applied | 1.48 | 1.39 |
| Normal incident | 11.35 | 5.17 | 4.03 |
| light | | | |
| Cone (0 to 8°) | 1.05 | 0.57 | 0.45 |
| incident light | | | |

As seen from FIGS. 10 and 11, and Table 1, when an ARL is applied, optical reflectance is reduced in a central area of the image sensor 1000 compared with the case in which an ARL is not applied. It may be seen that when the refractive index of the ARL is 1.39, which is closer to an ideal refractive index considering the refractive index of the sensing layer 600, there is a greater effect of improving optical reflectance. The average reflectance is about 4.03% and about 5.17% when ARLs with a refractive index of 1.39 and 1.48 are applied, respectively, which is seen to be improved compared with about 11.35% when an ARL is not applied.

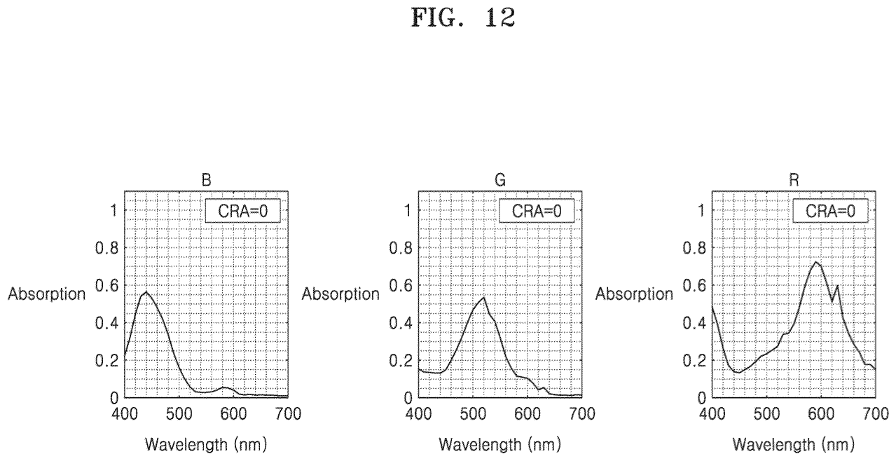

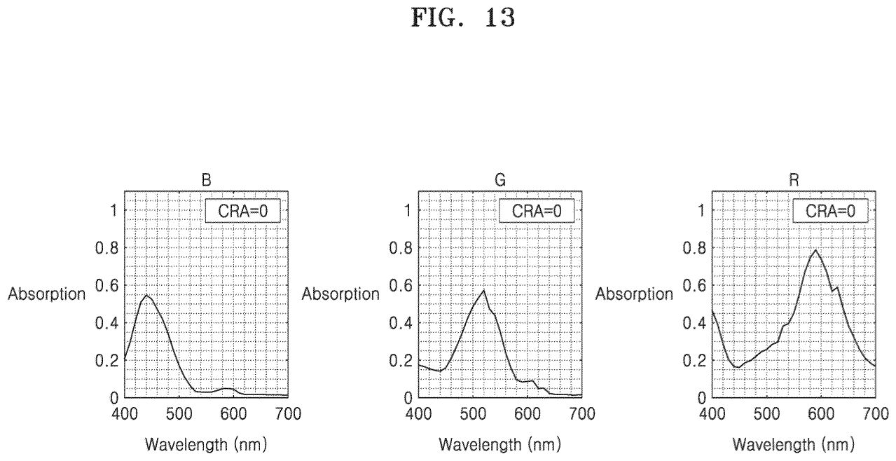

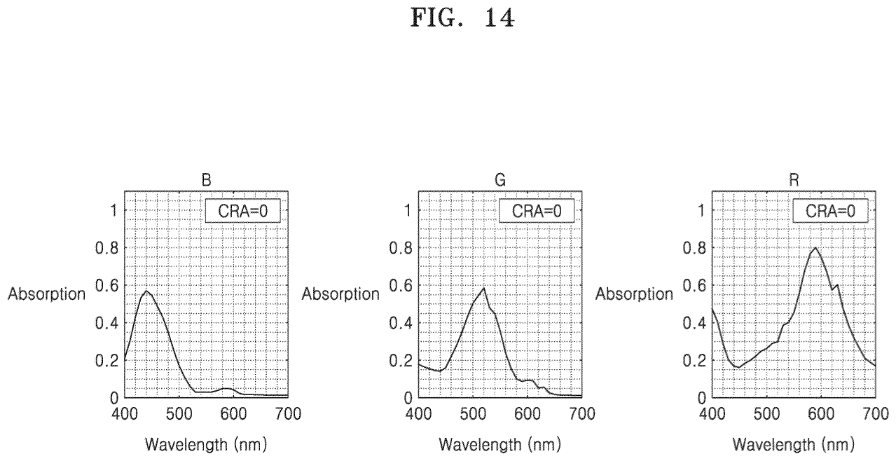

FIG. 12 shows results of computational simulation for color separation of blue (B), green (G), and red (R) light in a central area of the image sensor 1000 when an ARL is not applied, by using graphs that illustrate the absorption percentages of blue, green, and red lights across various wavelengths. FIG. 13 shows the results of computational simulation for color separation of blue, green, and red light in a central area of the image sensor 1000 when an ARL with a refractive index of 1.48 is applied, by using graphs that illustrate the absorption percentages of blue, green, and red lights across various wavelengths. FIG. 14 shows the results of computational simulation for color separation of blue (B), green (G), and red (R) light in a central area of the image sensor 1000 when an ARL with a refractive index of 1.39 is applied, by using graphs that illustrate the absorption percentages of blue, green, and red lights across various wavelengths. As seen from FIGS. 12 to 14, even if an ARL is applied, color separation performance of blue, green, and red is maintained in a central area of the image sensor 1000.

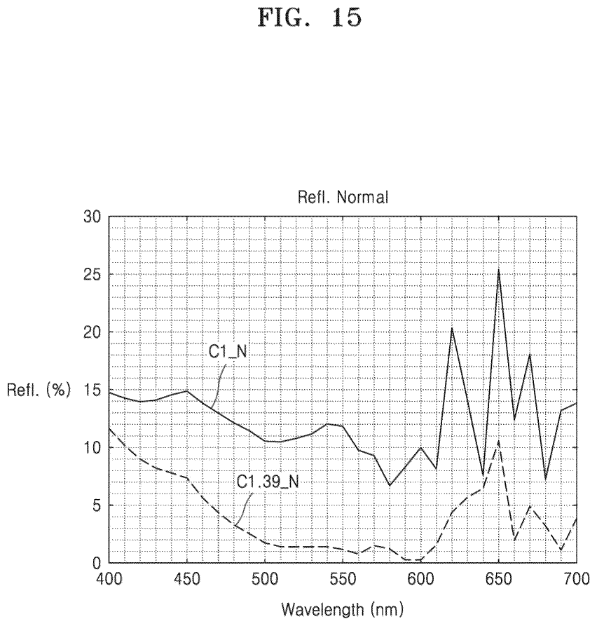

When an ARL is applied, whether optical reflectance is improved may be checked via computational simulation for optical reflectance in an outer area of the image sensor 1000, for example, an area with CRA=30. FIG. 15 is a graph showing an example of results of computational simulation on optical reflectance for normal incident light incident on an outer area of the image sensor 1000 when an ARL is applied and when the ARL is not applied. The conditions of the computational simulation are the same as those of FIGS. 10 to 14 described above. In FIG. 15, C1_N represents optical reflectance for normal incident light when an ARL is not applied, and C1.39_N represents optical reflectance for normal incident light when an ARL with a refractive index of 1.39 is applied. As seen from FIG. 15, when an ARL is applied, optical reflectance is reduced in an outer area of the image sensor 1000 compared with the case in which an ARL is not applied. The average reflectance is about 4.1% when an ARL is applied, which is seen to be improved compared with about 12.6% when an ARL is not applied.

FIG. 16 shows the results of computational simulation for color separation of blue (B), green (G), and red (R) light in an outer area of the image sensor 1000 when an ARL is not applied, by using graphs that illustrate the absorption percentages of blue, green, and red lights across various wavelengths. FIG. 17 shows the results of computational simulation for color separation of blue (B), green (G), and red (R) light in an outer area of the image sensor 1000 when an ARL with a refractive index of 1.39 is applied, by using graphs that illustrate the absorption percentages of blue, green, and red lights across various wavelengths. As seen from FIGS. 16 and 17, even if an ARL is applied, color separation performance of blue, green, and red is maintained in an outer area of the image sensor 1000.

As seen from the above computational simulation results, optical reflectance may be reduced to almost the same level in the central area and the outer area of the image sensor 1000 by applying an ARL. Accordingly, refractive indices of an ARL with respect to the central area and the outer area of the image sensor 1000 may be equalized, and thus a structure of the ARL may be simplified, and the ARL may be easily manufactured. A process defect rate of the image sensor 1000 may also be reduced. It may be seen that, even if an ARL is applied, the color separation performance of blue, green, and red light is maintained in both the central area and the outer area of the image sensor 1000.

In the image sensor 1000, both the average reflectance and the maximum reflectance need to be 2% or less. A range of the refractive index of an ARL may be determined within a range in which optical reflectance is 2% or less and color separation performance is to be maintained, considering the refractive index of the sensing layer 600, and the result is expressed in the inequation (1) described above. An exemplary process for determining a range of a refractive index of an ARL through computational simulation is as follows.

Conditions for computational simulation are explained. As shown in FIG. 5, in the pixel PX, the first photodiode 100, the second photodiode 200, and the two third photodiodes 300 are arranged at vertices of a square. The first photodiode 100 and the second photodiode 200 face each other in a diagonal direction, and the two third photodiodes 300 face each other in another diagonal direction. d_{R}, d_{G}, d_{B}, and d_{S} are 120 nm, 90 nm, 70 nm, and 150 nm, respectively. The first photodiode 100, the second photodiode 200, and the third photodiode 300 include polysilicon. The surrounding material 500 include SiO₂. The refractive index of the sensing layer 600, n_{S}, considering the volume fraction of the first photodiode 100, the second photodiode 200, and the third photodiode 300 and the volume fraction of the surrounding material 500, is about 1.82. In this case, a refractive index of an ideal ARL is

$$\sqrt{{n}_{s} \times {n}_{AIR}} \approx 1.35 .$$

An ARL has a multilayer structure. The thickness of the first layer is set to 10 nm, and the thickness of the second layer is set to 120 nm. The first layer is set to an ALO (Al₂O₃) layer, and the second layer is set to an SiO₂ layer. A refractive index of the first layer is set to about 1.77, and a refractive index of the second layer is set to about 1.48. When a refractive index of the first layer is n_{ALO} and a refractive index of the second layer is n_{SiO}, a refractive index considering the volume fractions of the first layer and the second layer is

$${n}_{A R L} = \frac{1}{13} \times {n}_{A L O} + \frac{12}{13} \times {n}_{S i O} .$$

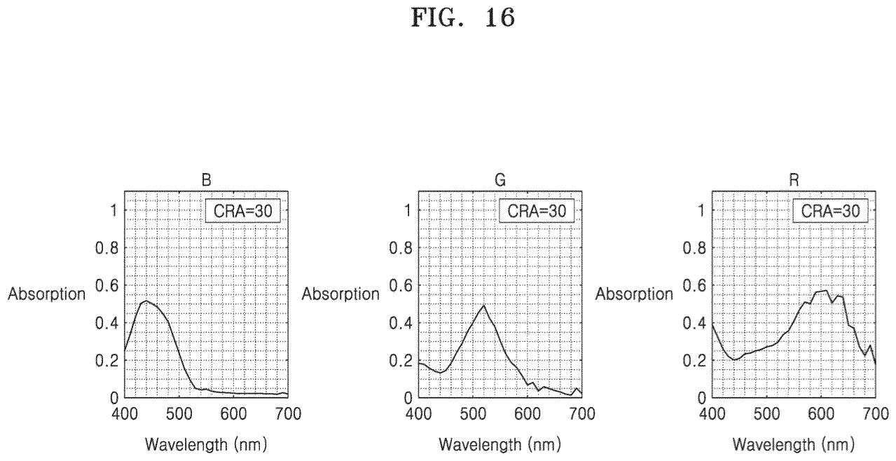

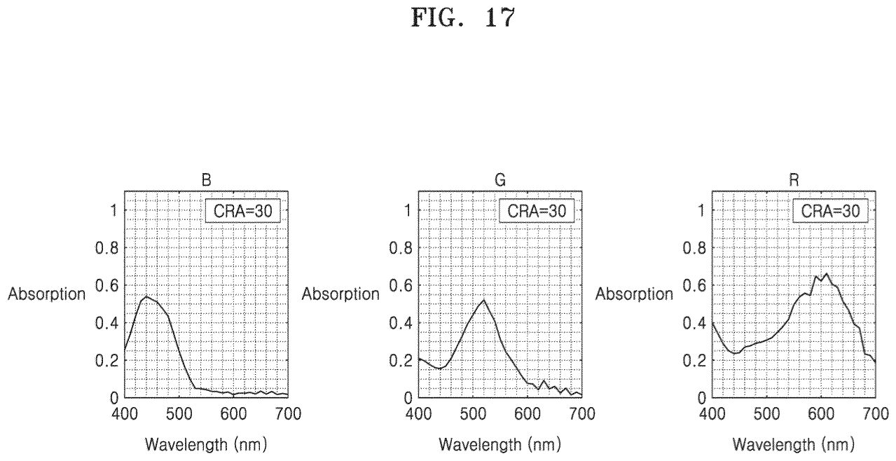

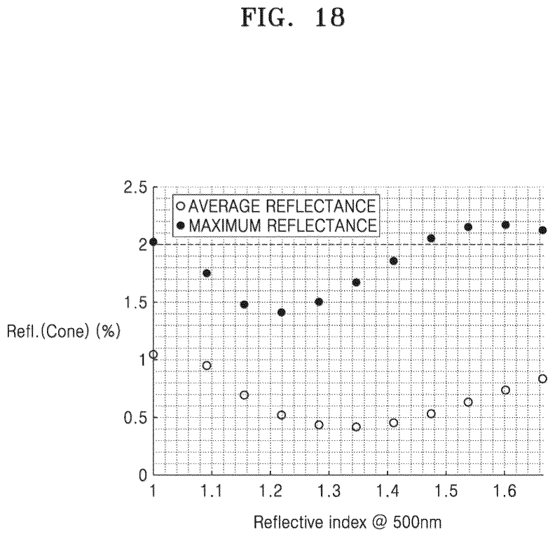

When the second layer has an air hole pattern, to obtain an effect of changing a volume fraction of the air hole pattern, a refractive index of an ARL is calculated while a refractive index of the second layer is changed from about −25% to about +20% in units of 5%, and average reflectance and maximum reflectance for cone incident light of about 0 degree to about 8 degrees may be calculated for each case. The calculation results are as shown in a graph in FIG. 18.

Referring to FIG. 18, when a refractive index of an ARL is about 1.41 or less, both the average reflectance and the maximum reflectance are in the range of 2% or less. Upon interpolating for the maximum value of the refractive index of the ARL, in which both the average reflectance and the maximum reflectance are 2%, the maximum value is about 1.455. This is about 1.08 times an ideal refractive index of the ARL of 1.35. Therefore, the range of the refractive index of the ARL may be determined by inequation (1). Computational simulation results regarding color separation performance show that color separation performance is maintained within the range in which the refractive index of the ARL is 1<n_{ARL}≤1.455.

In the case of the ARL 610a having hole patterns 612 as shown in FIG. 7, the refractive index of the ARL 610a satisfies the range of inequation (1) by adjusting the volume fraction of the hole patterns 612. As shown in FIG. 8, in the case of the ARL 610b in which a plurality of flat ARLs are stacked, the refractive index of the ARL 610b satisfies the range of inequation (1) by adjusting the thickness of at least one of the plurality of flat ARLs. As shown in FIG. 9, in the case of the ARL 610c having a structure in which the first layer 615 and the second layer 616 having a hole pattern 617 are stacked, the refractive index of the ARL 610c satisfies the range of inequation (1) by fixing thickness of the first layer 615 and adjusting the volume fraction of the hole patterns 617 of the second layer 616.

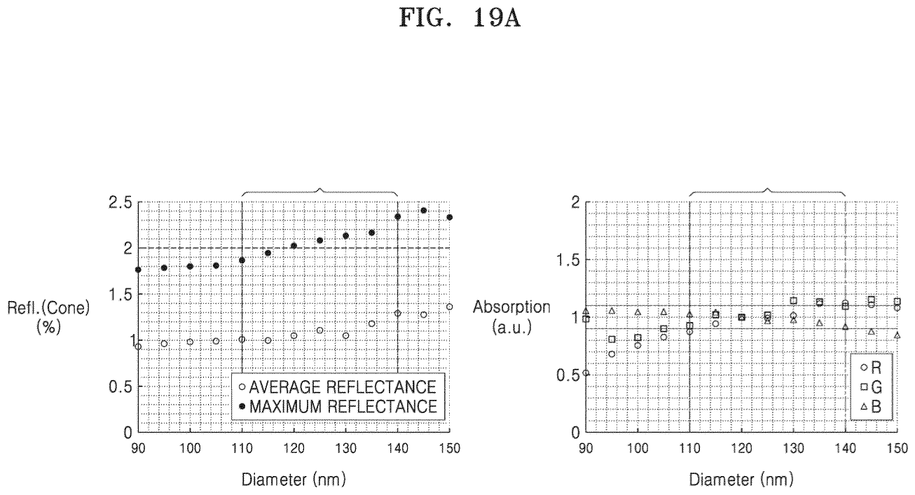

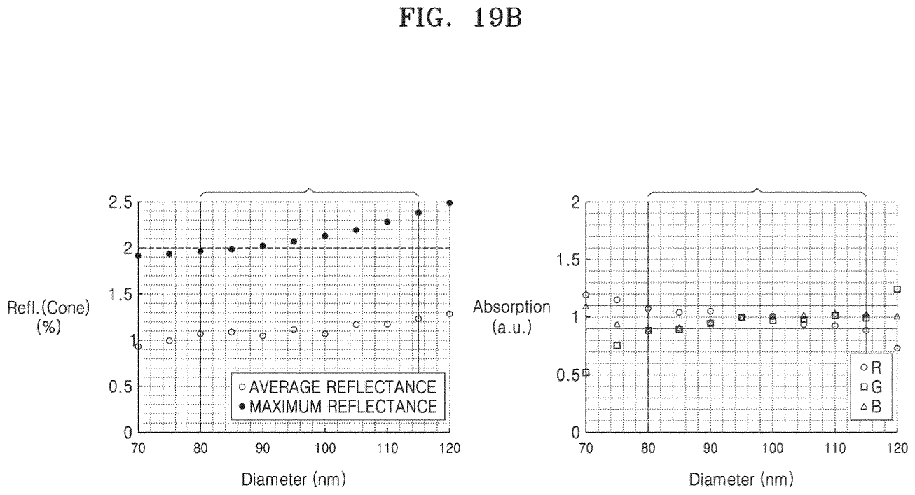

FIG. 19A shows the results of computational simulation for reflectance and color separation performance while changing a size d_{R} of the first photodiode 100. FIG. 19B shows the results of computational simulation for reflectance and color separation performance while changing a size d_{G} of the second photodiode 200. FIG. 19C shows the results of computational simulation for reflectance and color separation performance while changing a size d_{B} of the third photodiode 300.

Referring to FIG. 19A, as a result of computational simulation for color separation based on a size d_{R} of the first photodiode 100 of 120 nm, a change in color separation may be within ±10% in the range of about −10 nm to about +20 nm, that is, the size d_{R} of the first photodiode 100 of about 110 nm to about 140 nm. Referring to FIG. 19B, as a result of computational simulation for color separation based on a size d_{G} of the second photodiode 200 of 90 nm, a change in color separation may be within ±10% in the range of about −10 nm to about +25 nm, that is, the size d_{R} of the second photodiode 200 of about 80 nm to about 115 nm. Referring to FIG. 19C, as a result of computational simulation for color separation based on a size d_{B} of the third photodiode 300 of 70 nm, a change in color separation may be within ±10% in the range of about −10 nm to about +5 nm, that is, the size d_{B} of the third photodiode 300 of about 60 nm to about 75 nm. In each case, the maximum reflectance partially exceeds 2%, but the maximum reflectance may be maintained within 2% by applying the ARL described above.

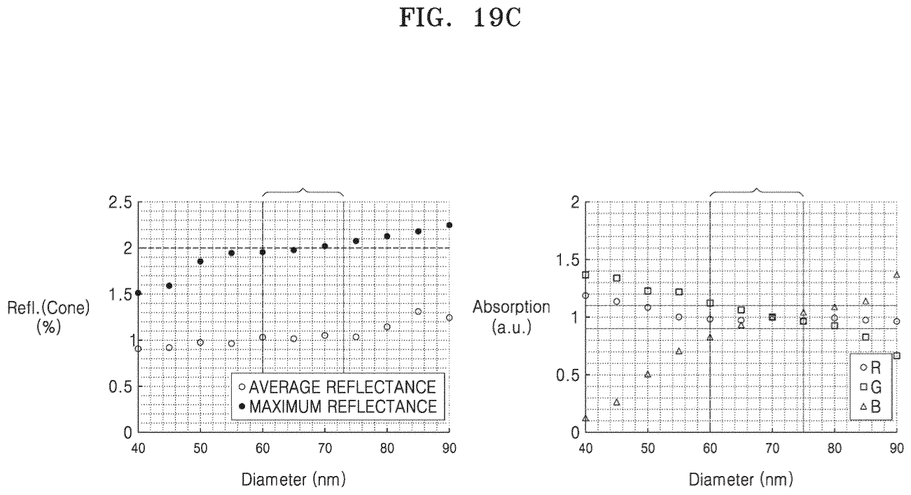

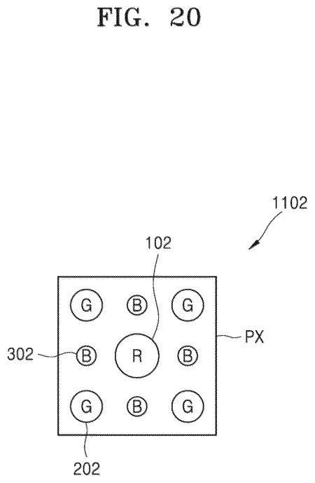

The type and arrangement of two or more photodiodes 700 within the pixel PX are not limited to the example shown in FIG. 5. FIGS. 20 to 22 are plan views showing examples of photodiodes provided in the pixel PX.

Referring to FIG. 20, a full color pixel PX constituting a pixel array 1102 may include one first photodiode 102 that selectively absorbs red light, a plurality of second photodiodes 202 that selectively absorb green light, and a plurality of third photodiodes 302 that selectively absorb blue light. The first photodiode 102 may be located at the center of the pixel PX, and four second photodiodes 202 and four third photodiodes 302 may be located to surround the first photodiode 102 in a square shape. Unlike in the drawings, the positions of the second photodiode 202 and the third photodiode 302 may be changed to each other.

Referring to FIG. 21, in a pixel array 1103, the full color pixels PX may be arranged in a hexagonal grid. One full color pixel PX may include one first photodiode 103 that selectively absorbs red light, three second photodiodes 203 that selectively absorb green light, and three second photodiodes 303 that selectively absorb blue light. The first photodiode 103 may be located at the center of the hexagon, and the second photodiode 203 and third photodiode 303 may be alternately located at each vertex of the hexagon.

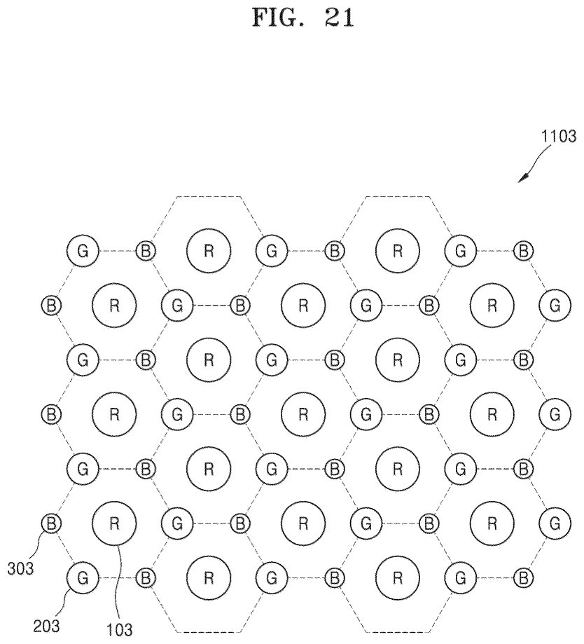

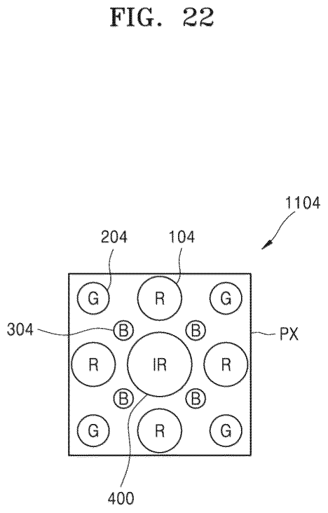

Referring to FIG. 22, the full color pixel PX of a pixel array 1104 may include a first photodiode 104 that selectively absorbs red light, a second photodiode 204 that selectively absorbs green light, and a third photodiode 304 that selectively absorbs blue light, and may further include a fourth photodiode 400 that selectively absorbs light in an infrared wavelength band.

A single fourth photodiode 400 may be located at the center, and the four first photodiodes 104, the four second photodiodes 204, and the four third photodiodes 304 may be arranged to surround the fourth photodiode 400. A diameter of the fourth photodiode 400 may be the greatest, for example, greater than 100 nm. A diameter of the third photodiode 300 may be set in the range of about 100 nm to about 200 nm.

As such, depth information in addition to color information about a subject may be further obtained from an image sensor including a photodiode that selectively absorbs an infrared wavelength band in addition to a photodiode that selectively absorbs R, G, and B colors. For example, a camera module including the image sensor may further include an infrared light source that emits infrared light to a subject, and infrared information sensed by the image sensor may be used to obtain depth information of the subject. That is, depth information of the subject may be obtained using infrared information sensed by the image sensor, and color information of the subject may be obtained using sensed visible light information. 3D image information may be obtained by combining color information and depth information.

The pixels PX provided in the image sensor 1000 are described as sensing R, G, and B colors, but may be modified to include a photodiode that may distinguish and detect light in different wavelength bands. For example, a plurality of photodiodes with different cross-sectional diameters, for example, 4, 8, or 16 photodiodes may be provided in one pixel to obtain a hyperspectral image in an ultraviolet to infrared wavelength range. One width of a pixel including these photodiodes may be set to λₘ or less, which is the shortest wavelength in the wavelength band. This is a value corresponding to the diffraction limit when assuming the F number of the imaging optical system is about 1.0. The minimum value of a pixel width may be set appropriately to the diameter and number of photodiodes provided in one pixel.

The pixels PX provided in the image sensor 1000 may be changed to include photodiodes sensing cyan/magenta/yellow colors and may also be configured to sense other multi colors.

The image sensor according to an embodiment may constitute a camera module with a module lens of various performances and may be used in various electronic apparatuses.

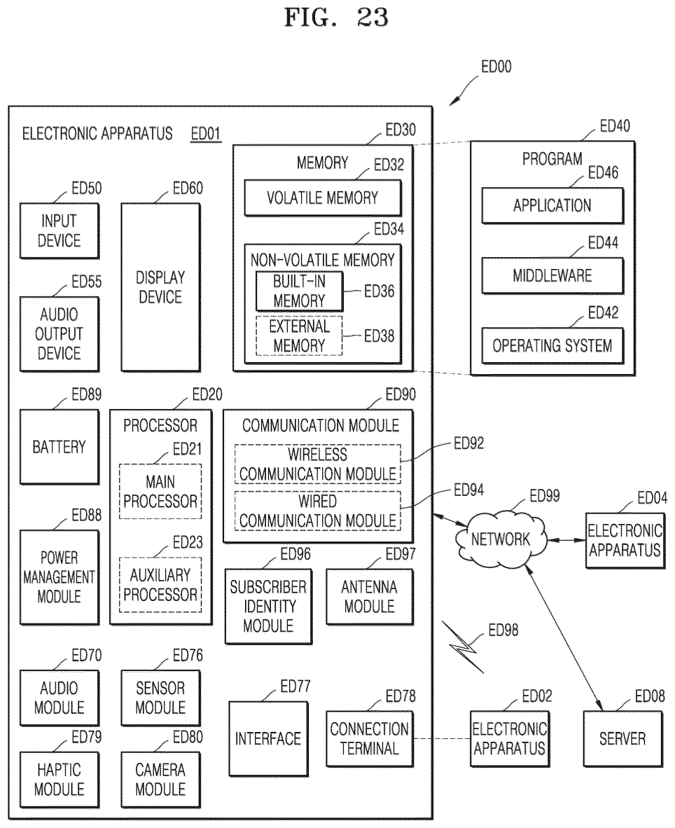

FIG. 23 is a block diagram illustrating an example of an electronic apparatus ED01 including the image sensor 1000. Referring to FIG. 23, in a network environment ED00, the electronic apparatus ED01 may communicate with another electronic apparatus ED02 through a first network ED98 (e.g., a short-range wireless communication network or the like) or communicate with another electronic apparatus ED04 and/or a server ED08 through a second network ED99 (e.g., a long-distance wireless communication network or the like). The electronic apparatus ED01 may communicate with the electronic apparatus ED04 through the server ED08. The electronic apparatus ED01 may include a processor ED20, a memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identity module ED96, and/or an antenna module ED97. In the electronic apparatus ED01, some of these components such as the display device ED60 may be omitted or other components may be added. Some of these components may be implemented as one integrated circuit. For example, the sensor module ED76 (e.g., a fingerprint sensor, an iris sensor, an illumination sensor, or the like) may be embedded in the display device ED60 (e.g., a display or the like).

The processor ED20 may execute software (e.g., a program ED40 or the like) to control one or a plurality of other components (e.g., hardware, software components, or the like) of the electronic apparatus ED01 connected to the processor ED20 and perform various data processing or calculations. As a portion of data processing or calculation, the processor ED20 may load commands and/or data received from other components (e.g., the sensor module ED76, the communication module ED90, or the like) into a volatile memory ED32, process commands and/or data stored in the volatile memory ED32, and store the resulting data in a non-volatile memory ED34. The processor ED20 may include a main processor ED21 (e.g., a central processing device, an application processor, or the like) and an auxiliary processor ED23 (e.g., a graphics processing device, an image signal processor, a sensor hub processor, a communication processor, or the like) that may operate independently therefrom or together therewith. The auxiliary processor ED23 may use less power than the main processor ED21 and perform specialized functions.

The auxiliary processor ED23 may control a function and/or a state related to some components (e.g., the display device ED60, the sensor module ED76, the communication module ED90, or the like) from among components of the electronic apparatus ED01 instead of the main processor ED21 while the main processor ED21 is in an inactive state (e.g., sleep state) or together with the main processor ED21 while the main processor ED21 is in an active state (e.g., application execution state). The auxiliary processor ED23 (e.g., an image signal processor, a communication processor, or the like) may also be implemented as a portion of other functionally related components (e.g., the camera module ED80, the communication module ED90, or the like).

The memory ED30 may store various data required by components (e.g., the processor ED20, the sensor module ED76, or the like) of the electronic apparatus ED01. Data may include, for example, input data and/or output data for software such as a program ED40 and instructions related thereto. The memory ED30 may include the volatile memory ED32 and/or the non-volatile memory ED34.

The program ED40 may be stored as software in the memory ED30 and may include an operating system ED42, middleware ED44, and/or an application ED46.

The input device ED50 may receive commands and/or data to be used in components (e.g., the processor ED20 or the like) of the electronic apparatus ED01 from an external source (e.g., a user or the like) of the electronic apparatus ED01. The input device ED50 may include a microphone, a mouse, a keyboard, and/or a digital pen (e.g., stylus pen or the like).

The audio output device ED55 may output an audio signal to the outside of the electronic apparatus ED01. The audio output device ED55 may include a speaker and/or a receiver. The speaker may be used for general purposes such as multimedia playback or recording playback, and the receiver may be used to receive incoming calls. The receiver may be integrated as a portion of the speaker or implemented as a separate independent device.

The display device ED60 may visually provide information to the outside of the electronic apparatus ED01. The display device ED60 may include a display, a hologram device, or a projector, and a control circuit for controlling the corresponding device. The display device ED60 may include a touch circuitry configured to detect a touch, and/or a sensor circuit such as a pressure sensor configured to measure the intensity of force generated by the touch.

The audio module ED70 may convert sound into electrical signals or, conversely, convert electrical signals into sound. The audio module ED70 may obtain sound through the input device ED50 or output sound through the audio output device ED55, and/or a speaker and/or a headphone of another electronic apparatus (e.g., the electronic apparatus ED02 or the like) directly or wirelessly connected to the electronic apparatus ED01.

The sensor module ED76 may detect an operating state (e.g., power, temperature, or the like) of the electronic apparatus ED01 or the external environmental state (e.g., a user state or the like) and generate electrical signals and/or data values corresponding to the detected state. The sensor module ED76 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface ED77 may support one or a plurality of designated protocols to be used to directly or wirelessly connect the electronic apparatus ED01 to another electronic apparatus such as the electronic apparatus ED02. The interface ED77 may include a high-definition multimedia interface (HDMI), a universal serial bus (USB) interface, an SD card interface, and/or an audio interface.

A connection terminal ED78 may include a connector through which the electronic apparatus ED01 is to be physically connected to another electronic apparatus such as the electronic apparatus ED02. The connection terminal ED78 may include an HDMI connector, a USB connector, a SD card connector, and/or an audio connector (e.g., a headphone connector or the like).

The haptic module ED79 may convert electrical signals into mechanical stimulation (e.g., vibration, movement, or the like) or electrical stimulation that a user is capable of perceiving through tactile or kinesthetic senses. The haptic module ED79 may include a motor, a piezoelectric element, and/or an electrical stimulation device.

The camera module ED80 may capture still images and videos. The camera module ED80 may include a lens assembly including one or a plurality of lenses, the image sensor 1000 of FIG. 1, image signal processors, and/or flashes. The lens assembly included in the camera module ED80 may collect light emitted from a subject that is a target of image capture.

The power management module ED88 may manage power supplied to the electronic apparatus ED01. The power management module ED88 may be implemented as a portion of a power management integrated circuit (PMIC).

The battery ED89 may supply power to components of the electronic apparatus ED01. The battery ED89 may include a non-rechargeable primary cell, a rechargeable secondary cell, and/or a fuel cell.

The communication module ED90 may establish a direct (wired) communication channel and/or a wireless communication channel between the electronic apparatus ED01 and other electronic apparatuses (e.g., the electronic apparatus ED02, the electronic apparatus ED04, the server ED08, or the like), and/or support communication through the established communication channel. The communication module ED90 may operate independently of the processor ED20 (e.g., an application processor or the like) and include one or more communication processors that support direct communication and/or wireless communication. The communication module ED90 may include a wireless communication module ED92 (e.g., a cellular communication module, a short-range wireless communication module, or a global navigation satellite system (GNSS) communication module) and/or a wired communication module ED94 (e.g., a local area network (LAN) communication module, a power line communication module, or the like). From among these communication modules, the corresponding communication module may communicate with other electronic apparatuses through the first network ED98 (e.g., a short-range communication network such as Bluetooth, WiFi Direct, or infrared data association (IrDA)) or the second network ED99 (e.g., a long-range communication network such as a cellular network, the Internet, or a computer network (e.g., LAN, WAN, or the like). These various types of communication modules may be integrated into one component (e.g., a single chip) or may be implemented as a plurality of separate components (e.g., multiple chips). The wireless communication module ED92 may check and authenticate the electronic apparatus ED01 such as the first network ED98 and/or the second network ED99 by using subscriber information (e.g., international mobile subscriber identifier (IMSI) or the like) stored in the subscriber identity module ED96.

The antenna module ED97 may transmit or receive signals and/or power to or from the outside (such as other electronic apparatuses). The antenna may include a radiator with a conductive pattern formed on a substrate (e.g., a printed circuit board (PCB) or the like). The antenna module ED97 may include one or a plurality of antennas. When the antenna module ED97 includes the plurality of antennas, an antenna suitable for a communication method used in a communication network such as the first network ED98 and/or the second network ED99 may be selected from among the plurality of antennas by the communication module ED90. Signals and/or power may be transmitted or received between the communication module ED90 and other electronic apparatuses through the selected antenna. In addition to the antenna, other components (e.g., a radio-frequency integrated circuit (RFIC) or the like) may be included as a portion of the antenna module ED97.

Some of the components are connected to each other through communication methods between peripheral devices (e.g., a bus, general purpose input and output (GPIO), a serial peripheral interface (SPI), a mobile industry processor interface (MIPI), or the like) and exchange signals (e.g., commands, data, or the like) with each other.

Commands or data may be transmitted or received between the electronic apparatus ED01 and an external electronic apparatus ED04 through the server ED08 connected to the second network ED99. The other electronic apparatuses ED02 and ED04 may be the same or different types of apparatuses from the electronic apparatus ED01. All or some of the operations performed in the electronic apparatus ED01 may be executed in one or more of the other electronic apparatuses ED02, ED04, and ED08. For example, when the electronic apparatus ED01 needs to perform a certain function or service, the electronic apparatus ED01 may request one or more other electronic apparatuses to perform some or all of the functions or services instead of executing the functions or services independently. One or more other electronic apparatuses that receive the request may execute additional functions or services related to the request and transmit the results of the execution to the electronic apparatus ED01. To this end, cloud computing, distributed computing, and/or client-server computing technologies may be used.

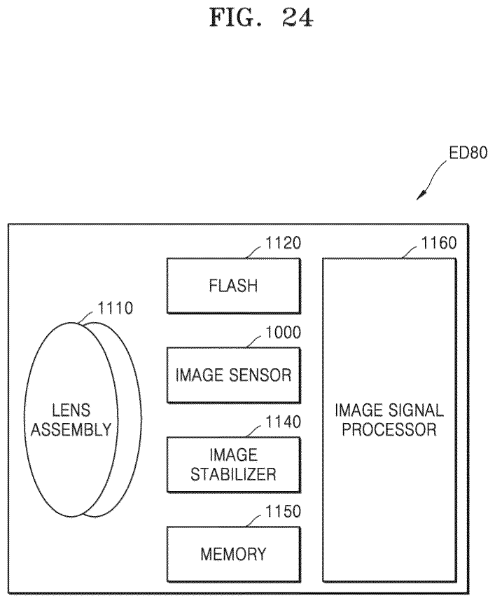

FIG. 24 is a block diagram illustrating the camera module ED80 provided in the electronic apparatus ED01 of FIG. 23. Referring to FIG. 24, the camera module ED80 may include a lens assembly 1110, a flash 1120, the image sensor 1000, an image stabilizer 1140, a memory 1150 (e.g., a buffer memory or the like), and/or an image signal processor 1160. The lens assembly 1110 may collect light emitted from a subject that is a target of image capture. The camera module ED80 may include a plurality of lens assemblies 1110, and in this case, the camera module ED80 may be a dual camera, a 360-degree camera, or a spherical camera. Some of the plurality of lens assemblies 1110 may have the same lens properties (e.g., angle of view, focal length, autofocus, F number, optical zoom, or the like) or may have different lens properties. The lens assembly 1110 may include a wide-angle lens or a telephoto lens.

The flash 1120 may emit light used to enhance light emitted or reflected from a subject. The flash 1120 may emit visible light or infrared light. The flash 1120 may include one or more light emitting diodes (e.g., red-green-blue (RGB) LED, white LED, infrared LED, ultraviolet LED, or the like), and/or a xenon lamp. The image sensor 1000 may be the image sensor described in FIG. 1 and may obtain an image corresponding to the subject by converting light emitted or reflected from the subject and transmitted through the lens assembly 1110 into an electrical signal.

The image sensor 1000 may be the image sensor 1000 of FIG. 1 described above, and the type and arrangement of photodiodes included in the pixel PX provided therein have the form described in FIGS. 5, and 20 to 22, or a combination or modified form thereof. A plurality of pixels in the image sensor 1000 may have a small pixel width, for example, a width less than or equal to the diffraction limit. A width, p, of each of the plurality of pixels provided in the image sensor 1000 satisfies a condition of

p<λF

Here, F is a F number of the lens assembly 1110, and λ is a center wavelength of a blue wavelength band.

The image stabilizer 1140 may move one or more lenses or image sensors 1000 included in the lens assembly 1110 in a certain direction in response to movement of the camera module ED80 or an electronic apparatus 1101 including the same or compensate for a negative effect due to movement by controlling the operation characteristics of the image sensor 1000 (e.g., adjustment of read-out timing or the like). The image stabilizer 1140 may detect movement of the camera module ED80 or the electronic apparatus ED01 by using a gyro sensor or an acceleration sensor located inside or outside the camera module ED80. The image stabilizer 1140 may be implemented optically.

The memory 1150 may store some or all data of an image obtained through the image sensor 1000 for a subsequent image processing operation. For example, when a plurality of images are obtained at high speed, the obtained original data (e.g., Bayer-patterned data, high-resolution data, or the like) may be stored in the memory 1150, and a low-resolution image alone may be displayed, and may then be used to transmit the selected (e.g., user selection or the like) to the image signal processor 1160. The memory 1150 may be integrated into the memory ED30 of the electronic apparatus ED01, or may be configured as a separate memory that operates independently.

The image signal processor 1160 may perform image processing on the image obtained through the image sensor 1000 or the image data stored in the memory 1150. Image processing may include depth map creation, 3D modeling, panorama creation, feature point extraction, image compositing, and/or image compensation (e.g., noise reduction, resolution adjustment, brightness adjustment, blurring, sharpening, softening, or the like). The image signal processor 1160 may perform control (e.g., exposure time control, lead-out timing control, or the like) on components such as the image sensor 1000 included in the camera module ED80. Images processed by the image signal processor 1160 may be re-stored in the memory 1150 for further processing or provided to external components of the camera module ED80 (e.g., the memory ED30, the display device ED60, the electronic apparatus ED02, the electronic apparatus ED04, the server ED08, or the like). The image signal processor 1160 may be integrated into the processor ED20 or may be configured as a separate processor that operates independently of the processor ED20. When the image signal processor 1160 is configured as a separate processor from the processor ED20, additional image processing may be performed on the image processed by the image signal processor 1160 and then the image may be displayed through the display device ED60.

When the image sensor 1000 includes a photodiode that selectively absorbs an infrared wavelength band and photodiodes that selectively absorb red light, green light, and blue light as illustrated in FIG. 22, the image signal processor 1160 may process the infrared signal and the visible light signal obtained from the image sensor 1000 together. The image signal processor 1160 may obtain a depth image of the subject by processing an infrared signal, obtain a color image of the subject from a visible light signal, and combine the depth image and the color image to provide a 3D image of the subject. The image signal processor 1160 may also calculate information about temperature or moisture of the subject from infrared signals, and may also provide temperature distribution and moisture distribution images combined with a 2D image (e.g., a color image) of the subject.

The electronic apparatus ED01 may further include one or more camera modules, each having different properties or functions. This camera module may also include a configuration similar to the camera module ED80 of FIG. 22, and the image sensor provided therein may be implemented as a charged coupled device (CCD) sensor and/or a complementary metal oxide semiconductor (CMOS) sensor, and may include one or more sensors selected from image sensors with different properties, such as an RGB sensor, a black and white (BW) sensor, an IR sensor, or a UV sensor. In this case, one of the plurality of camera modules ED80 may be a wide-angle camera and the other may be a telephoto camera. Similarly, one of the plurality of camera modules ED80 may be a front camera and the other may be a rear camera.

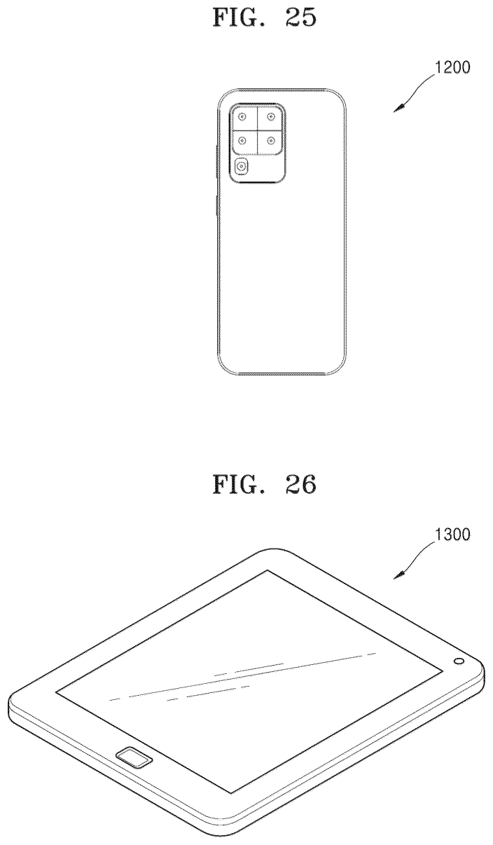

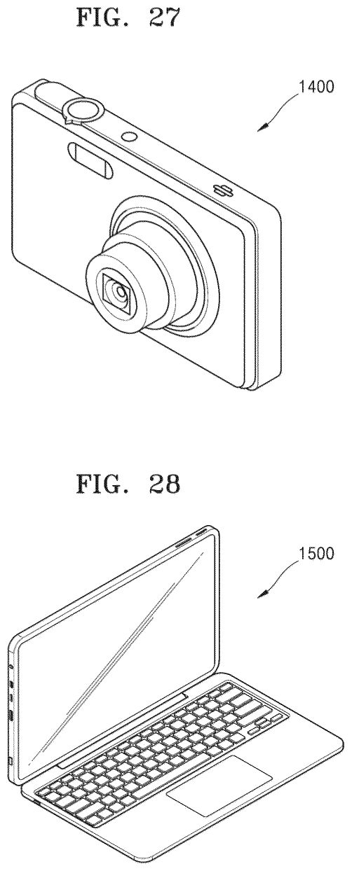

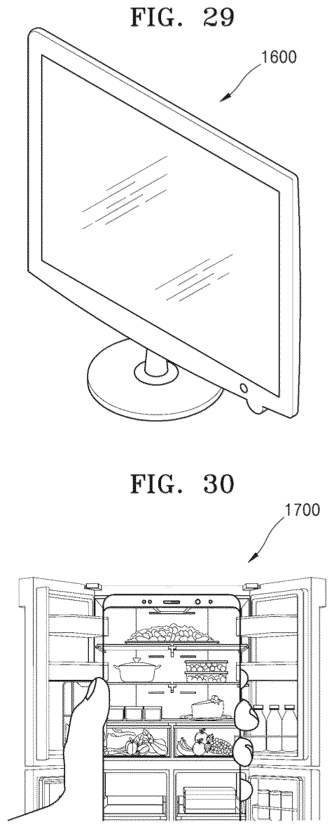

The image sensor 1000 according to embodiments may be applied to a mobile phone or smartphone 1200 shown in FIG. 25, a tablet or smart tablet 1300 shown in FIG. 26, a digital camera or camcorder 1400 shown in FIG. 27, a laptop computer 1500 shown in FIG. 28, or a television or smart television 1600 shown in FIG. 29. For example, the smartphone 1200 or the smart tablet 1300 may include a plurality of high-resolution cameras each including a high-resolution image sensor. Depth information of subjects in an image may be extracted, out of focus of an image may be adjusted, or subjects in an image may be automatically identified using high-resolution cameras.

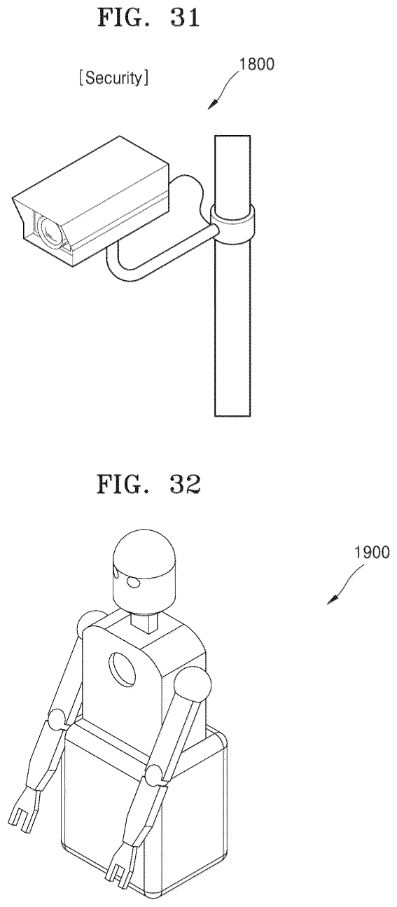

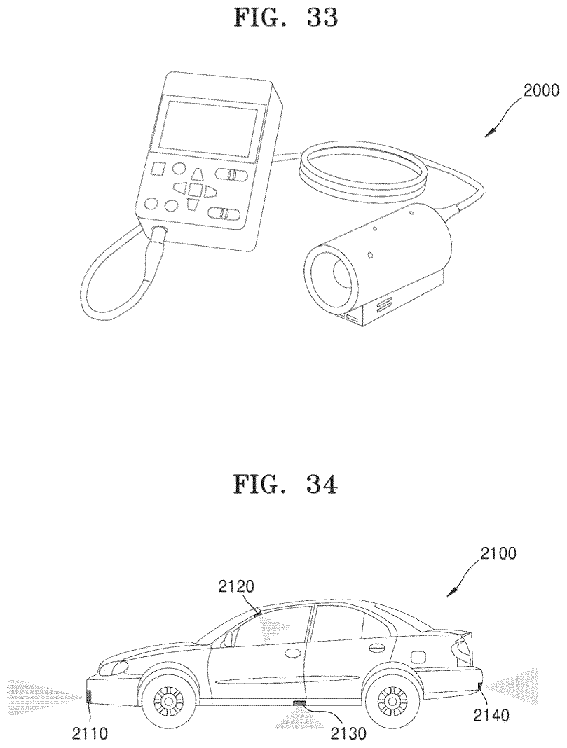

The image sensor 1000 may be applied to a smart refrigerator 1700 shown in FIG. 30, a security camera 1800 shown in FIG. 31, a robot 1900 shown in FIG. 32, a medical camera 2000 shown in FIG. 33, or the like. For example, the smart refrigerator 1700 may automatically recognize food in a refrigerator by using an image sensor and inform a user of presence or absence of certain food, and a type of received or delivered food, through a smartphone. The security camera 1800 may provide an ultra-high resolution image and recognize objects or people in the image even in a dark environment by using high sensitivity. The robot 1900 may provide a high-resolution image when deployed at disaster or industrial sites that are not to be directly accessed by humans. The medical camera 2000 may provide high-resolution images for diagnosis or surgery and may dynamically adjust a field of view thereof. The image sensor 1000 may also be applied to a virtual reality device, an augmented reality device, or the like.

The image sensor 1000 may be applied to a vehicle 2100 as shown in FIG. 34. The vehicle 2100 may include a plurality of vehicle cameras 2110, 2120, 2130, and 2140 arranged at various locations, and each of the vehicle cameras 2110, 2120, 2130, and 2140 may include an image sensor 1000 according to the embodiment. The vehicle 2100 may provide a driver with various information about the inside or surroundings of the vehicle 2100 by using the plurality of vehicle cameras 2110, 2120, 2130, and 2140, and automatically recognizes objects or people in the image to provide information necessary for autonomous driving.

Although the image sensor and the electronic apparatus including the same described above are described with reference to the embodiment shown in the drawings, this is merely an example, and various modifications and other equivalent embodiments may be made by those skilled in the art. Therefore, the disclosed embodiments need to be considered from an illustrative rather than a restrictive perspective. The scope of the disclosure is indicated in the claims, not the foregoing description, and all differences within the equivalent scope need to be interpreted as being included in the scope of the disclosure.

In the image sensor according to embodiments, individual pixels having a small width less than a diffraction limit may distinguish and detect respective lights of a plurality of types of wavelength bands. Therefore, components such as color separation elements and color filters may not be used, and high light efficiency may be obtained.

The image sensor according to embodiments may produce an image with high color purity and no flare or ghost artifacts by employing an ARL.

The image sensor according to embodiments may be used as a multi-color sensor, a multi-wavelength sensor, or a hyper-spectral sensor, and may be used as a 3D image sensor that provides both a color image and a depth image. The image sensor according to the embodiments described above may be applied as a high-resolution camera module and used in various electronic apparatuses.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. An image sensor comprising:
a plurality of pixels, each of the plurality of pixels comprising:
a sensing layer including a first photodiode configured to absorb light in a red wavelength band, a second photodiode configured to selectively absorb light in light in a green wavelength band, a third photodiode configured to selectively absorb light in light in a blue wavelength band, and a filling material provided around the first photodiode, the second photodiode, and the third photodiode; and
an anti-reflection layer (ARL) provided on a light incident surface of the sensing layer to lower reflectance of light incident on the sensing layer,
wherein a refractive index of the ARL satisfies 1<n_{ARL}≤1.08×\sqrt{n_{S}×n_{AIR}}, when n_{ARL} denotes the refractive index of the ARL is n_{ARL}, n_{S} denotes a refractive index of the sensing layer is n_{S}, and n_{AIR} denotes a refractive index of air.

2. The image sensor of claim 1, wherein the ARL has a thickness in a range from 50 nm to 200 nm.

3. The image sensor of claim 1, wherein a ratio of a thickness of the ARL to a thickness of the sensing layer is in a range from 1/50 to 1/2.5.

4. The image sensor of claim 1, wherein the ARL has a single-layer structure.

5. The image sensor of claim 4, wherein the ARL has a flat surface.

6. The image sensor of claim 4, wherein the ARL comprising a coating layer covering the surface of the sensing layer and a plurality of hole patterns provided in the coating layer.

7. The image sensor of claim 1, wherein the ARL has a multi-layer structure.

8. The image sensor of claim 7, wherein the ARL comprises a first layer covering the surface of the sensing layer and a second layer on the first layer.

9. The image sensor of claim 8, wherein the first layer comprises a passivation layer.

10. The image sensor of claim 8, wherein the first layer and the second layer comprise flat ARLs having different refractive indices.

11. The image sensor of claim 8, wherein the first layer comprises a flat ARL, and a plurality of hole patterns are provided in the second layer.

12. The image sensor of claim 1, wherein the ARL comprises at least one of ALO, Al₂O₃, HfO, LTO, SiN, SiO₂, AlOC, AlON, MgF₂, and AlOCN.

13. The image sensor of claim 1, wherein each of the first, the second, and the third photodiodes comprises polysilicon, and
the refractive index of the ARL satisfies 1<n_{ARL}≤1.455.

14. The image sensor of claim 1, wherein each of the first, the second, and the third photodiodes has a rod shape comprising a first conductive type semiconductor layer, an intrinsic semiconductor layer, and a second conductive type semiconductor layer, the first conductive type semiconductor layer, the intrinsic semiconductor layer, and the second conductive type semiconductor layer being stacked in one direction,
cross-sections of the first, the second, and the third photodiodes have a first width, a second width, and a third width, respectively, in a direction perpendicular to the one direction, and
the first width, the second width, and the third width satisfy w1>w2>w3 when w1, w2, and w3 denote the first width, the second width, and the third width, respectively.

15. The image sensor of claim 14, wherein each of the plurality of pixels comprises four photodiodes consisting of the first photodiode, the second photodiode, the third photodiode, and an additional third photodiode.

16. The image sensor of claim 15, wherein the first, the second, and the third photodiodes are arranged in a square shape formed by a line connecting centers of the four photodiodes.

17. The image sensor of claim 16, wherein the third photodiodes are arranged in a diagonal direction of the square shape.

18. The image sensor of claim 17, wherein the first width is in a range from 110 nm to 140 nm, the second width is in a range from 80 nm to 115 nm, and the third width is in a range from 60 nm to 75 nm.

19. An electronic apparatus comprising:
a lens assembly including one or more lenses and configured to form an optical image of a subject;
the image sensor of claim 1, configured to convert the optical image into an electrical signal; and
a processor configured to process the electrical signal generated by the image sensor.

20. An image sensor comprising a plurality of pixels, each of the plurality of pixels comprising:
a sensing layer comprising:
a plurality of photodiodes that extend in a vertical direction, that are spaced apart from each other in a horizontal direction, and that are configured to absorb light in a red wavelength band, in a green wavelength band, and in a blue wavelength band, respectively, and
a filling material that fill gaps between the plurality of photodiodes; and
an anti-reflection layer provided on a light incident surface of the sensing layer and configured to lower light reflectance on the image sensor,
wherein the image sensor is configure to selectively absorb the light in the red wavelength band, in the green wavelength band, and in the blue wavelength band through the plurality of photodiodes without using a color filter.
